(19) United States
(12) Patent Application Publication
(10) Pub. No.: US 2026/0033078 A1
(43) Pub. Date: Jan. 29, 2026

(54) Display Device

(71) Applicant: LG Display Co., Ltd., Seoul (KR)

(72) Inventors: Taehyeon Woo, Ulsan (KR); Jinyoung Kim, Gumi-si (KR)

(21) Appl. No.: 19/246,251

(22) Filed: Jun. 23, 2025

(30) Foreign Application Priority Data
Jul. 26, 2024 (KR) 10-2024-0099453

(51) Int. Cl. H10H 29/49; H10H 29/41; H10H 29/85

(52) U.S. Cl. CPC H10H 29/49; H10H 29/41; H10H 29/8508

(57) ABSTRACT

A display device may include a substrate including a display area and a non-display area outside the display area; a plurality of pixel driving circuits disposed on the display area of the substrate; a plurality of light-emitting elements disposed on the pixel driving circuit and electrically connected to each pixel driving circuit; a plurality of pad electrodes disposed on the non-display area of the substrate; at least one or more multilayer insulating structure disposed in a lower side of the plurality of pad electrodes; and one or more reinforcement patterns disposed between the pad electrode and the multilayer insulating structure.

### CROSS-REFERENCE TO RELATED APPLICATION

This application claims priority from Republic of Korea Patent Application No. 10-2024-0099453 filed on Jul. 26, 2024, which is hereby incorporated by reference in its entirety.

### BACKGROUND

### Field

This disclosure relates to a display device.

### Description of Related Art

Display devices are applied to various electronic devices such as televisions (TVs), mobile phones, laptops, and tablets.

The display devices may be classified into organic light-emitting display (OLED) apparatuses having self-luminous properties, and liquid crystal display (LCD) apparatuses requiring a separate light source.

Recently, display devices including a light-emitting diode (LED) (hereinafter, referred to as a “light-emitting element”) are attracting attention as next-generation display devices. Since the light-emitting element is not configured with organic materials but inorganic materials, it can light up faster than the liquid crystal display device or the organic light-emitting display device, have excellent light-emitting efficiency, and display high-brightness images.

### SUMMARY

Typically, the display device may include a plurality of pad electrodes. The pad electrode may be electrically connected to a driving component including a flexible circuit board or a printed circuit board. The plurality of pad electrodes may transmit various signals or powers from the flexible circuit board and printed circuit board to a display area.

To ensure the reliability of the display device, it is important to stably transmit signals or powers from the flexible circuit board and printed circuit board to the display area.

The pad electrode may be connected with the flexible circuit board or printed circuit board via a conductive adhesive layer. The multilayer insulating structure disposed in the lower side of the pad electrode is vulnerable to physical pressure, and so microcracks or micro displacements may occur due to external force, which may deteriorate the electrical connection.

In view of the above, the inventors of the present disclosure have, through various experiments, invented a display device capable of maintaining the reliability of electrical connection by preventing microcracks or micro displacements from occurring in the multilayer insulating structure disposed in the lower side of the pad electrode.

An object to be achieved according to an embodiment of the present disclosure is to provide a display device capable of maintaining the reliability of electrical connection of the pad electrode with the flexible circuit board and the printed circuit board.

In addition, another object to be achieved according to an embodiment of the present disclosure is to provide a display device capable of preventing microcracks or film displacements in the multilayer insulating structure disposed in the lower side of the pad electrode.

The objects to be accomplished according to an embodiment of the present disclosure are not limited to the ones described above, and other objects and advantages of the present invention which are not mentioned can be understood from the following description, and will be more clearly understood from the embodiments of the present invention. Furthermore, it will be readily appreciated that the objects and advantages of the present disclosure can be realized by the means presented in the claims, and combinations thereof.

A display device according to an embodiment of the present disclosure may include a substrate including a display area and a non-display area outside the display area; a plurality of pixel driving circuits disposed on the display area of the substrate; a plurality of light-emitting elements disposed on the pixel driving circuit and electrically connected to each pixel driving circuit; a plurality of pad electrodes disposed on the non-display area of the substrate; at least one or more multilayer insulating structure disposed in a lower side of the plurality of pad electrodes; and one or more reinforcement patterns disposed between the pad electrode and the multilayer insulating structure.

According to an embodiment of the present disclosure, by disposing the reinforcement pattern within a multilayer insulating structure to be disposed in the lower side of an area corresponding to the pad electrode, it is possible to prevent the problematic situation where the microcracks or micro displacements occur and cause the organic insulating material to be recessed due to conductive balls of the adhesive layer.

Thus, film displacements caused by micro cracks or micro displacements can be prevented. Accordingly, the reliability of the display device can be improved due to the provision of an electrical connection capable of stably transmitting multiple signals or powers to the display area.

In addition, it is possible to prevent or at least reduce defects from occurring in the light-emitting element due to the prevention of exposure to the cleaning solution and resulting corrosion of the layer including the conductive material. Thereby, it is possible to provide a display device capable of implementing the same brightness with the reduced power consumption.

The present disclosure may have other effects besides the aforementioned ones, which are clearly recognizable to a person skilled in the art from the description below.

### BRIEF DESCRIPTION OF DRAWINGS

FIG. 1 is an exploded perspective view of a display device according to an embodiment of the present disclosure.

FIG. 2 is a plan view of a display device according to an embodiment of the present disclosure.

FIG. 3 is an enlarged view of a display device according to an embodiment of the present disclosure.

FIG. 4 is a diagram showing a circuit structure according to an embodiment of the present disclosure.

FIG. 5 is a plan view of a display device according to an embodiment of the present disclosure.

FIG. 6 is a plan view of a display device according to an embodiment of the present disclosure.

FIG. 7 is a plan view of a display device according to an embodiment of the present disclosure.

FIG. 8 is a cross-sectional view of a display device according to an embodiment of the present disclosure.

FIG. 9 is a cross-sectional view of a display device according to an embodiment of the present disclosure.

FIGS. 10 to 13 are views illustrating devices to which display devices according to embodiments of the present disclosure are applied.

FIG. 14 is a plan view showing an area where one pixel driving circuit of a plurality of pixel driving circuits is arranged according to embodiments of the present disclosure are applied.

FIG. 15 is an enlarged plan view showing area ‘I’ in FIG. 2 according to the first embodiment of the present disclosure.

FIG. 16 is a cross-sectional view taken along line II-II′ in FIG. 15 according to embodiments of the present disclosure are applied.

FIG. 17 is a cross-sectional view showing a pad electrode with an adhesive layer disposed on the upper side thereof according to embodiments of the present disclosure are applied.

FIG. 18 is a cross-sectional view showing a pad part according to a second embodiment of the present disclosure.

FIG. 19 is a cross-sectional view showing a pad part according to a third embodiment of the present disclosure.

FIG. 20 is a cross-sectional view showing a pad part according to a fourth embodiment of the present disclosure.

FIG. 21 is a cross-sectional view showing a pad part according to a fifth embodiment of the present disclosure.

### DETAILED DESCRIPTIONS

Advantages and features of the present disclosure, and a method of achieving the advantages and features will become apparent when referring to the following embodiments described later in detail together with the accompanying drawings. However, the present disclosure is not limited to the embodiments as disclosed below, but may be embodied in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for illustrating embodiments of the present disclosure are illustrative, and the present disclosure is not limited thereto. Throughout the detailed description, like reference numerals refer to like components. Further, in describing the present disclosure, if it is determined that a detailed description of a related known technology may unnecessarily obscure the gist of the present disclosure, the detailed description thereof will be omitted. When the terms “comprise”, “include,” “have,” “configure,” and the like are used in this disclosure, the presence or addition of other element may be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using “on”, “above”, “below”, “under”, and “next to”, one or more other elements may be interposed between the two elements unless the term “just”, “directly”, or “close” is used.

In describing a temporal relationship, for example, when the temporal order is described as “after”, “subsequent”, “next”, and “before”, the case which is not continuous may also be included unless the term “just” or “directly” is used.

It will be understood that, although the terms “first”, “second”, etc. may be used herein to describe various elements, these elements should not be limited by these terms. These terms are only used to distinguish one element from another element. So, a first element referred to in the following description may represent a second element, without departing from the scope of the technical idea of the present disclosure. In describing components herein, terms such as first, second, A, B, (a), or (b) may be used. These terms are only intended to distinguish one component from another, and do not limit the nature, order, sequence, or number of the components.

When a component is described as being “connected to,” “coupled to,” “access to,” or “attached to” another component, such component may be directly connected to, coupled to, contact with, or attached to the other component. However, it should be understood that they may be indirectly connected to, coupled to, access to, or attached to each other with still another component interposed therebetween, unless explicitly stated to the contrary.

When a component or layer is described as “being in contact with,” or “overlapping with” another component or layer, such component or layer may directly be in contact with or overlap with the other component or layer, and, however, it should be understood that they may also indirectly be in contact with or overlap with each other with still another component or layer interposed between, unless explicitly stated to the contrary.

The expression “at least one” should be understood to include any combination of one or more of the associated components. For example, the meaning of “at least one of the first, second, and third components” may include not only the first, second, or third component, but also any combination of two or more of the first, second, and third components.

The terms “first direction”, “second direction”, “third direction”, “X-axis direction”, “Y-axis direction”, and “Z-axis direction” should not be interpreted as merely geometric relationships in which the relationship between them is perpendicular to each other, but may mean a wider directionality within the range in which the configuration of the present disclosure can act functionally.

The individual features of the various embodiments of the present disclosure may be coupled or combined with each other in part or in whole to be interconnected and operated in a variety of technical ways, and each embodiment may be implemented independently of each other or implemented together in an associative relationship.

Hereinafter, various embodiments of the present disclosure will be described in detail with reference to the accompanying drawings.

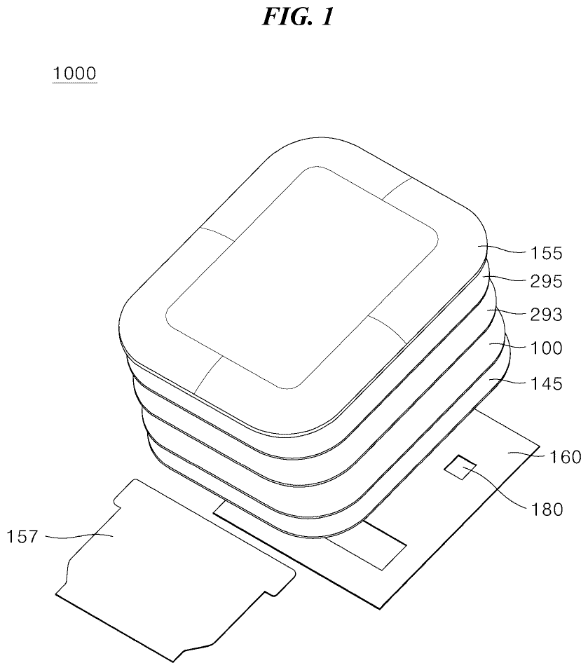

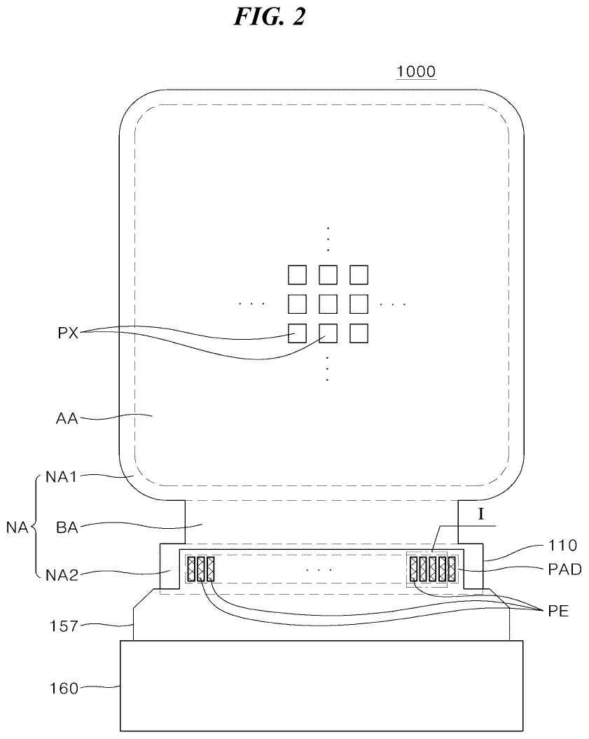

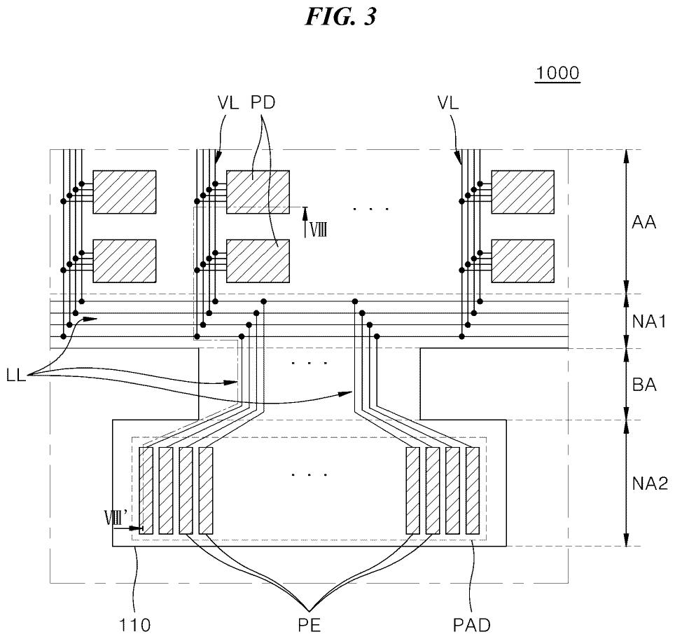

FIG. 1 is an exploded perspective view of a display device according to an embodiment of the present disclosure. FIG. 2 is a plan view of a display device according to an embodiment of the present disclosure. FIG. 3 is an enlarged view of a display device according to an embodiment of the present disclosure.

Referring to FIGS. 1 to 3, a display device 1000 according to an embodiment of the present disclosure may include a display panel 100, a polarizing layer 293, an adhesive layer 295, a cover member 155, a support substrate 145, a flexible circuit board 157, and a printed circuit board 160.

For example, the display device 1000 may include a substrate 110. The substrate 110 may be a member that supports other components of the display device 100. The substrate 110 may be configured with an insulating material. For example, the substrate 110 may be configured with glass or resin. Alternatively, the substrate 110 may be configured with a material having flexibility. For example, the substrate 110 may be configured with a plastic material having flexibility, such as polyimide (PI). However, the embodiments of the present disclosure are not limited thereto.

The display panel 100 can implement information, video, and/or images to be provided to a user. For example, the display panel 100 may include a display area AA and a non-display area NA. For example, the substrate 110 may include the display area AA and the non-display area NA. The description for the display area AA and non-display area NA are not limited to the substrate 110, but may be applicable throughout the display device 1000.

The display area AA may be an area where an image is displayed. The display area AA may include a plurality of pixels PX. Each of the plurality of pixels PX may be constituted with a plurality of sub-pixels. At each of the plurality of sub-pixels a plurality of light-emitting elements may be disposed. The plurality of light-emitting elements may be configured differently depending on the kinds of display device 1000. For example, in a case where the display device 1000 is an inorganic light-emitting display device, the light-emitting element may be an LED (Light-emitting Diode), a Micro LED (Micro Light-emitting Diode), or a Mini LED (Mini Light-emitting Diode), but the embodiments of the present disclosure are not limited thereto.

The non-display area NA may be an area where an image is not displayed. In the non-display area NAA, various wirings and circuits for driving a plurality of pixels PX in the display area AA may be disposed. For example, in the non-display area NA, there may be disposed a pad part PAD on which various wirings and driving circuits may be mounted and to which integrated circuits and printed circuits are connected, but the embodiments of the present disclosure are not limited thereto.

For example, the driving circuit may be a data driving circuit and/or a gate driving circuit, but the embodiments of the present disclosure are not limited thereto. In the non-display area NA, there may be disposed wirings through which control signals for controlling the driving circuits are supplied. For example, the control signal may include various timing signals including synchronization signals, an input data enable signal, and a clock signal, but the embodiments of the present disclosure are not limited thereto. The control signal may be received through the pad part PAD. For example, in the non-display area NA, there may be disposed link wirings LL for transmitting a signal. For example, driving components such as the flexible circuit board 157 and the printed circuit board 160 may be connected to the pad part PAD.

According to the present disclosure, the non-display area NA may include a first non-display area NA1, a bending area BA, and a second non-display area NA2. For example, the first non-display area NA1 may be an area surrounding at least a portion of the display area AA. The bending area BA may be an area which is bendable and extends from at least one of a plurality of sides of the first non-display area NA1. The second non-display area NA2 may be an area which extends from the bending area BA, and in which the pad part PAD may be disposed. For example, the bending area BA may be in a bent state, and the remaining area of the substrate 110 except the bending area BA may be in a flat state. In this case, as the bending area BA is bent, the second non-display area NA2 can be located on the rear surface of the display area AA. However, the embodiments of the present disclosure are not limited thereto.

The display area AA of the substrate 110 or the display device 1000 may be configured in various shapes depending on the designs of the display device 1000. For example, the display area AA may be configured in a rectangular shape with four rounded corners, but the embodiments of the present disclosure are not limited thereto. For another example, the display area AA may be configured in a rectangular shape with four right angles, a circular shape, or the like, but the embodiments of the present disclosure are not limited thereto.

According to the present disclosure, the width of the second non-display area NA2 in which a plurality of pad electrodes PE are disposed may be greater than the width of the bending area BA in which the plurality of link wirings LL are disposed. Additionally, the width of the display area AA in which the plurality of sub-pixels are disposed may be greater than the width of the bending area BA in which only the plurality of link wirings LL are disposed. Although the width of the bending area BA is depicted in the drawing as being smaller than the widths of other areas of the substrate 110, the shape of the substrate 110 including such bending area BA is given only as an example, and the embodiments of the present disclosure are not limited thereto.

Referring to FIG. 3, in the display area AA, there may be disposed a plurality of pixel driving circuits PD. The plurality of pixel driving circuits PD may be circuits for driving light-emitting elements of a plurality of sub-pixels. For example, each of the plurality of pixel driving circuits PD may perform the functions of a driving transistor, a storage capacitor and the like. For example, each of the plurality of pixel driving circuits PD may control the light-emitting operation of the plurality of light-emitting elements of the sub-pixel by supplying a control signal, a power, and a driving current to the plurality of light-emitting elements. For example, a pixel driving circuit PD may include a power wiring and a signal wiring for controlling the on/off and/or light-emitting time of a light-emitting element. For example, the plurality of pixel driving circuits PD may be driving drivers manufactured on a semiconductor substrate using a metal-oxide-silicon field effect transistor (MOSFET) manufacturing process, but the embodiments of the present disclosure are not limited thereto. The driving driver may drive a plurality of sub-pixels. For example, the plurality of pixel driving circuits PD may include a micro driver μDriver, but the embodiments of the present disclosure are not limited thereto. For example, the plurality of pixel driving circuits PD may be implemented in the form of a driving chip.

Referring to FIG. 1 together, the flexible circuit board 157 and the printed circuit board 160 may be disposed at the lower side of the display panel 100. The flexible circuit board 157 and the printed circuit board 160 may be disposed at least on one edge of the display panel 100, but the embodiments of the present disclosure are not limited thereto. The flexible circuit board 157 may be attached to the display panel 100 at its one side, and to the printed circuit board 160 at another side thereof, but the embodiments of the present disclosure are not limited thereto. The flexible circuit board 157 may be configured with a flexible film, but the embodiments of the present disclosure are not limited thereto.

In the second non-display area NA2, the pad part PAD may be disposed, which includes the plurality of pad electrodes PE. A driving component including one or more flexible circuit boards (or flexible films) 157 and the printed circuit boards 160 may be attached or bonded to the pad part PAD. The plurality of pad electrodes PE of the pad part PAD may be electrically connected to one or more flexible circuit boards (or flexible films) 157 to transmit various signals or power from the printed circuit board 160 and the flexible circuit board (or flexible film) 157 to the plurality of pixel driving circuits PD in the display area AA.

The flexible circuit board (or flexible film) 157 may be configured with a film whose base film has a flexibility and is provided with various components disposed thereon. For example, the flexible circuit board (or flexible film) 157 may be provided with a driving IC such as a gate driving IC or a data driving IC disposed thereon, but the embodiments of the present disclosure are not limited thereto. The driving IC may be a kind of a component that processes data and driving signals for displaying an image. The driving IC may be disposed in a manner such as a Chip On Glass (COG), a Chip On Film (COF), or a Tape Carrier Package (TCP) depending on the mounting method, but the embodiments of the present disclosure are not limited thereto. The flexible circuit board (or flexible film) 157 may be attached or bonded onto the plurality of pad electrodes PE via a conductive adhesive layer, but the embodiments of the present disclosure are not limited thereto.

The printed circuit board 160 may be a kind of a component electrically connected to one or more flexible circuit boards (or flexible films) 157 to supply signals to the driving integrated circuit (IC). The printed circuit board 160 may be disposed at one side of the flexible circuit board (or flexible film) 157 to be electrically connected to the flexible circuit board (or flexible film) 157. On the printed circuit board 160, there may be disposed a range of components for supplying various signals to the driving IC. For example, on the printed circuit board 160 a variety of components, including a timing controller, a power supply, a memory, a processor, or the like, may be disposed. For example, the printed circuit board 160 may be provided with a power management integrated circuit PMIC, but the embodiments of the present disclosure are not limited thereto.

The printed circuit board 160 may include at least one hole 180, but the embodiments of the present disclosure are not limited thereto. In an area corresponding to at least one hole 180, there may be disposed an internal component detecting ambient light, temperature or the like, which may be provided with a plurality of sensors. For example, the internal component may include an ambient light sensor (ALS) or a temperature sensor, but embodiments of the present disclosure are not limited thereto. For example, the hole 180 may be a kind of a permeable hole, but the embodiments of the present disclosure are not limited thereto.

Referring to FIG. 1, the polarizing layer 293 may be disposed on the display panel 100. The polarizing layer 293 can prevent or alleviate a phenomenon in which the light generated by an external light source enters the inside of the display panel 100 and affects the light-emitting element or the like.

The cover member 155 may be disposed on the polarizing layer 293. The cover member 155 may be a member for protecting the display panel 100. The adhesive layer 295 may be disposed between the polarizing layer 293 and the cover member 155. By the adhesive layer 295 the cover member 155 can be attached to the display panel 100. The adhesive layer 295 may include an optically clear adhesive (OCA), an optically clear resin (OCR), a pressure sensitive adhesive (PSA), or the like, but the embodiments of the present disclosure are not limited thereto.

The support substrate 145 may be disposed between the display panel 100 and the printed circuit board 160. The support substrate 145 can reinforce the rigidity of the display panel 100. The support substrate 145 may be a kind of a back plate, but the embodiments of the present disclosure are not limited thereto.

Referring to FIGS. 1 to 3, the plurality of link wirings LL may be disposed in the non-display area NA. The plurality of link wirings LL may be wirings that transmit various signals from one or more flexible circuit boards (or flexible films) 157 and the printed circuit boards 160 to the display area AA. The plurality of link wirings LL may extend from the plurality of pad electrodes PE in the second non-display area NA2 toward the bending area BA and the first non-display area NA1 to be electrically connected to a plurality of driving wirings VL in the display area AA. The plurality of pixel driving circuits PD can be driven by receiving signals from one or more flexible circuit boards (or flexible films) 157 and printed circuit boards 160 through the driving wirings VL in the display area AA and the link wirings LL in the non-display area NA.

For example, the plurality of driving wirings VL may be wirings for transmitting signals output from the flexible circuit board (or flexible film) 157 and the printed circuit board 160 to the plurality of pixel driving circuits PD together with the plurality of link wirings LL. The plurality of driving wirings VL may be disposed in the display area AA to be electrically connected to each of the plurality of pixel driving circuits PD. The plurality of driving wirings VL may extend from the display area AA toward the non-display area NA to be electrically connected to the plurality of link wirings LL.

When the bending area BA is bent, portions of the plurality of link wirings LL may be also bent together. Stress may be concentrated on a portion of the bent link wiring LL, which may cause cracks to occur in the link wiring LL. So, the plurality of link wirings LL may be configured with a conductive material having excellent ductility to reduce the cracks when the bending area BA is bent. For example, the plurality of link wirings LL may be configured with a conductive material having excellent ductility, such as gold Au, silver Ag, aluminum Al or the like, but the embodiments of the present disclosure are not limited thereto. Alternatively, the plurality of link wirings LL may be configured with one of various conductive materials used in the display area AA. For example, the plurality of link wirings LL may be configured with molybdenum (Mo), chromium (Cr), titanium (Ti), nickel (Ni), neodymium (Nd), copper (Cu), and an alloy of silver (Ag) and magnesium (Mg), or any alloy thereof, but the embodiments of the present disclosure are not limited thereto. The plurality of link wirings LL may be configured in a multilayer structure including various conductive materials. For example, the plurality of link wirings LL may be configured in a triple layer structure of titanium (Ti)/aluminum (Al)/titanium (Ti), but the embodiments of the present disclosure are not limited thereto.

The plurality of link wirings LL may be configured in various shapes to reduce stress. At least a portion of the plurality of link wirings LL disposed on the bending area BA may extend in the same direction as the extension direction of the bending area BA, or in a direction different from the extension direction of the bending area BA, to reduce stress. For example, in a case where the bending area BA extends in one direction from the first non-display area NA1 toward the second non-display area NA2, at least a portion of the link wiring LL disposed on the bending area BA may extend in a direction transverse to the one direction. As another example, at least a portion of the plurality of link wirings LL may be configured in patterns of various shapes. For example, at least a portion of the plurality of link wirings LL disposed on a bending area BA may have a shape in which a conductive pattern having at least one shape of a diamond shape, a rhombus shape, a trapezoidal wave shape, a triangular wave shape, a sawtooth wave shape, a sine wave shape, a circular shape, and an omega (52) shape may be repeatedly disposed, but the embodiments of the present disclosure are not limited thereto.

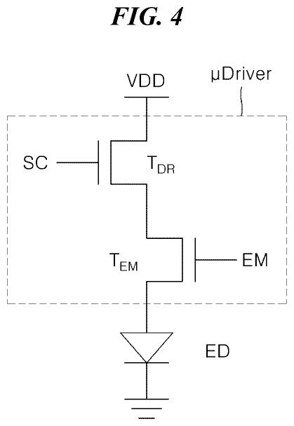

FIG. 4 is a diagram showing a circuit structure according to an embodiment of the present disclosure.

In FIG. 4, one light-emitting element ED is, by way of example, connected to a micro driver μDriver. However, this is not exhaustive. For example, one micro driver μDriver may control a plurality of pixels arranged on the substrate in sixteen columns by sixteen rows (16×16). The plurality of pixels may include a plurality of light-emitting elements ED.

One micro driver μDriver may be implemented in the form of a chip. For example, the micro driver μDriver implemented in the form of a chip may include circuits of a driving transistor TDR and a light-emitting transistor TEM.

For example, the driving transistor TDR in the micro driver μDriver may have a first electrode to which a high-potential power supply voltage VDD is applied, a second electrode to which a first electrode of the light-emitting transistor TEM is connected, and a gate electrode to which a scan signal SC is applied. The scan signal SC applied to the gate electrode of the driving transistor TDR may be a direct current (DC) power source, and a fixed reference voltage (Vref) may be applied every frame, but the embodiments of the present disclosure are not limited thereto.

The light-emitting transistor TEM may have the first electrode to which the second electrode of the driving transistor TDR is connected, a second electrode to which the light-emitting element ED is connected, and a gate electrode to which a light-emitting signal EM is applied. The light-emitting signal EM applied to the gate electrode of the light-emitting transistor TEM may be a pulse width modulation (PWM) signal that varies every frame, but the embodiments of the present disclosure are not limited thereto.

The light-emitting element ED may have the first electrode connected to the second electrode of the light-emitting transistor TEM, and a second electrode connected to ground. For example, the first electrode may be an anode electrode, and the second electrode may be a cathode electrode, but the embodiments of the present disclosure are not limited thereto.

The driving transistor TDR and the light-emitting transistor TEM may each be an n-type or a p-type transistor.

In the micro driver μDriver, the driving transistor TDR may be turned on by the scan signal SC applied from the timing controller T-CON, and the light-emitting transistor TEM may be turned on by the light-emitting signal EM. By this, a driving current can be applied to the light-emitting element ED via the driving transistor TDR and the light-emitting transistor TEM by the high-potential power supply voltage VDD applied to the first electrode of the driving transistor TDR, thereby causing the light-emitting element ED to emit light.

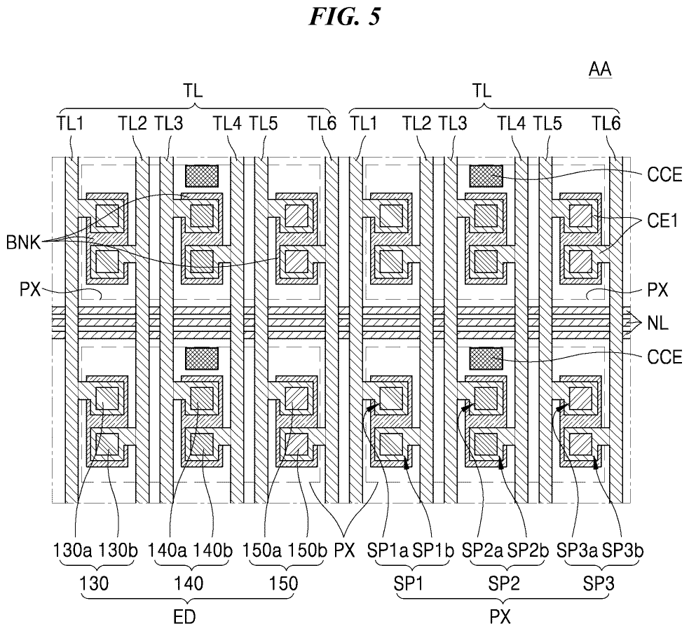

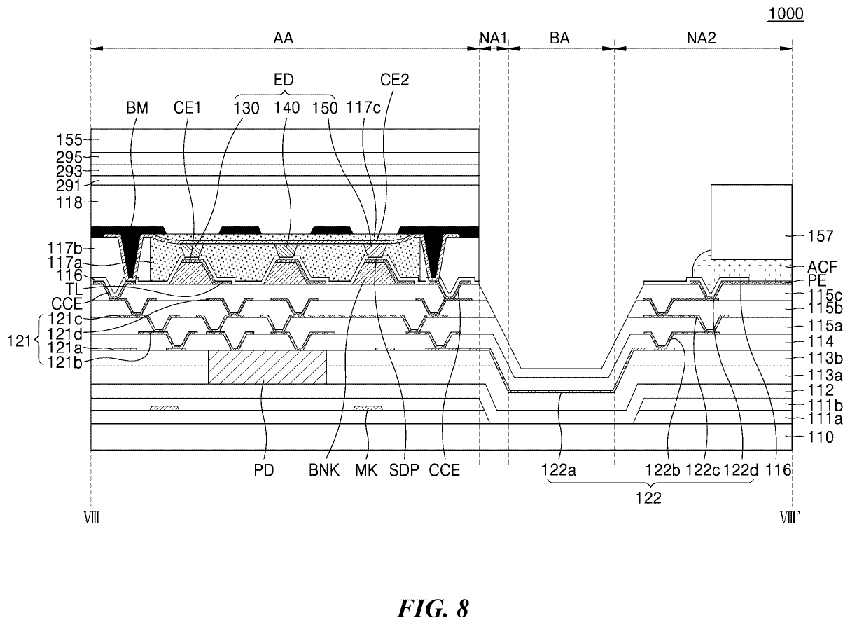

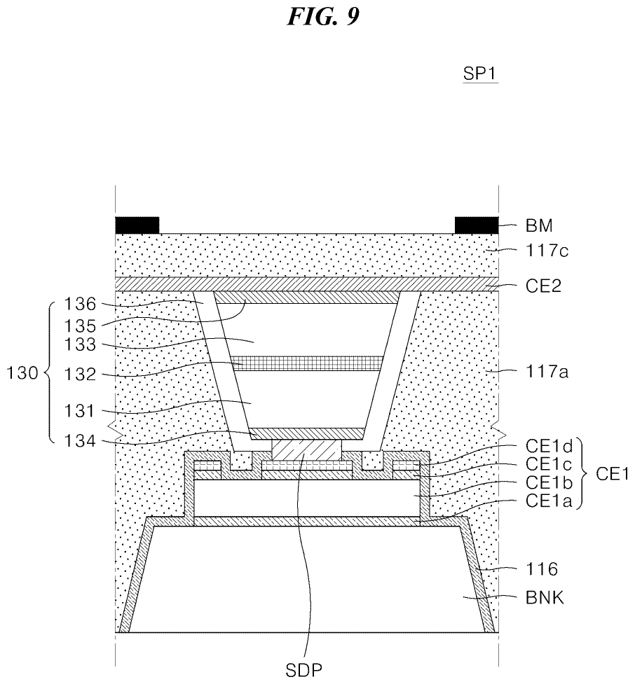

FIGS. 5 to 7 are plan views of a display device according to an embodiment of the present disclosure. FIGS. 8 and 9 are cross-sectional views of a display device according to an embodiment of the present disclosure.

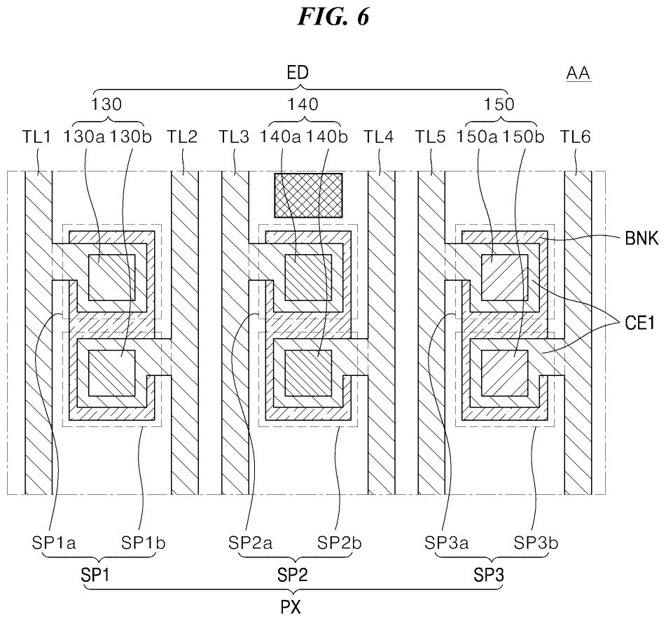

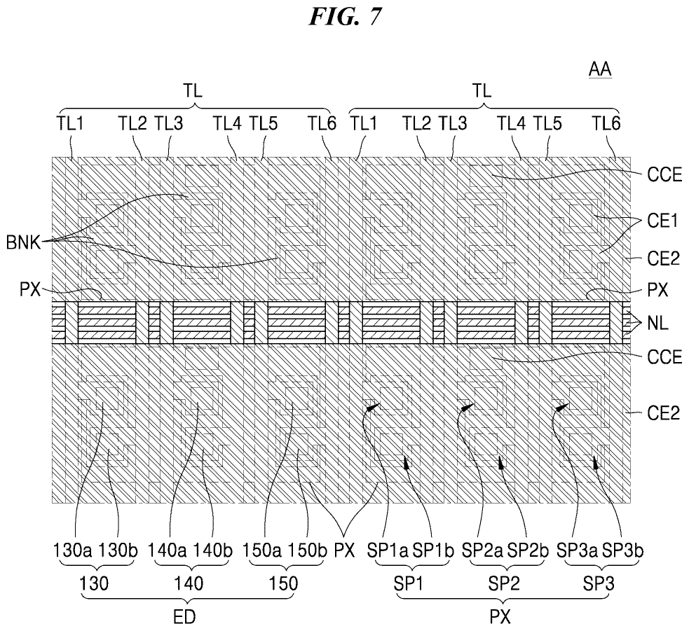

For example, FIG. 5 is an enlarged plan view of a display area including a plurality of pixels according to an embodiment of the present disclosure. For example, FIG. 6 is an enlarged plan view of a display area including one pixel according to an embodiment of the present disclosure. For example, FIG. 7 is an enlarged plan view of a display area including a plurality of pixels according to an embodiment of the present disclosure. For example, FIG. 8 is a cross-sectional view of the display area AA, the first non-display area NA, the bending area BA, and the second non-display area NA2 according to an embodiment of the present disclosure. For example, FIG. 9 is a cross-sectional view of a display area including one sub-pixel SP1 according to an embodiment of the present disclosure. In FIGS. 5 and 6, a plurality of signal wirings TL, a plurality of communication wirings NLs, a plurality of first electrodes CE1, a plurality of banks BNK, and a plurality of light-emitting elements ED are illustrated, but the embodiments of the present disclosure are not limited thereto. FIG. 7 is an enlarged plan view in which a plurality of second electrodes CE2 are additionally disposed to FIG. 5.

Referring to FIGS. 5, 6, and 9, a plurality of pixels PX configured with a plurality of sub-pixels may be disposed in the display area AA. Each of the plurality of sub-pixels may include a light-emitting element ED and can independently emit light. The plurality of sub-pixels may be disposed in a matrix form, forming a plurality of rows and a plurality of columns, but the embodiments of the present disclosure are not limited thereto.

The plurality of sub-pixels may include a first sub-pixel SP1, a second sub-pixel SP2, and a third sub-pixel SP3. For example, one of the first sub-pixel SP1, the second sub-pixel SP2 and the third sub-pixel SP3 may be a red sub-pixel, another thereof may be a green sub-pixel, and the remaining one thereof may be a blue sub-pixel. The types of the plurality of sub-pixels are given only as an example, and the embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may be configured with a first-first sub-pixel SP1a and a first-second sub-pixel SP1b. The pair of second sub-pixels SP2 may be configured with a second-first sub-pixel SP2a and a second-second sub-pixel SP2b. The pair of third sub-pixels SP3 may be configured with a third-first sub-pixel SP3a and a third-second sub-pixel SP3b. For example, one pixel PX may include the first-first sub-pixel SP1a and the first-second sub-pixel SP1b, the second-first sub-pixel SP2a and the second-second sub-pixel SP2b, and the third-first sub-pixel SP3a and the third-second sub-pixel SP3b, but the embodiments of the present disclosure are not limited thereto.

The plurality of sub-pixels constituting one pixel PX may be arranged in various ways. For example, in one pixel PX, the pair of first sub-pixels SP1 may be disposed in the same column, the pair of second sub-pixels SP2 may be disposed in the same column, and the pair of third sub-pixels SP3 may be disposed in the same column. The first sub-pixel SP1, the second sub-pixel SP2, and the third sub-pixel SP3 may be disposed in the same row. The number and arrangement of the plurality of sub-pixels constituting one pixel PX are given only as an example, and the embodiments of the present disclosure are not limited thereto.

The plurality of signal wirings TL may be disposed in the area between a plurality of sub-pixels. The plurality of signal wirings TL may extend in the column direction between the plurality of sub-pixels. The plurality of signal wirings TL may be wirings that transmit the anode voltage from the pixel driving circuit PD to the plurality of sub-pixels. For example, the plurality of signal wirings TL may be electrically connected to the plurality of pixel driving circuits PD and first electrodes CE1s of the plurality of sub-pixels. The anode voltage output from the pixel driving circuit PD may be transmitted to the first electrodes CE1s of the plurality of sub-pixels through the plurality of signal wirings TL. For example, the first electrode CE1 may be an electrode electrically connected to an anode electrode 134 of the light-emitting element ED. By this, the anode voltage from the signal wiring TL can be transmitted to the anode electrode 134 of the light-emitting element ED through the first electrode CE1.

Therefore, instead of forming a plurality of transistors and storage capacitors in each of the plurality of sub-pixels, by using the pixel driving circuit PD in which a plurality of pixel circuits are integrated, the structure of the display device 1000 can be simplified. In addition, since the circuits disposed in each of the plurality of sub-pixels are integrated into one pixel driving circuit PD, high-efficiency and low-power driving can be realized.

The plurality of signal wirings TL may include a first signal wiring TL1, a second signal wiring TL2, a third signal wiring TL3, a fourth signal wiring TL4, a fifth signal wiring TL5, and a sixth signal wiring TL6. Each of the first signal wiring TL1 and the second signal wiring TL2 may be electrically connected to each of the pair of first sub-pixels SP1. Each of the third signal wiring TL3 and the fourth signal wiring TL4 may be electrically connected to each of the pair of second sub-pixels SP2. Each of the fifth signal wiring TL5 and the sixth signal wiring TL6 may be electrically connected to each of the pair of third sub-pixels SP3.

The first signal wiring TL1 may be disposed at one side of the pair of first sub-pixels SP1, and the first signal wiring TL1 may be disposed at another side of the pair of first sub-pixels SP1. The first signal wiring TL1 may be electrically connected to the first electrode CE1 of one of the first sub-pixels SP1 of the pair of first sub-pixels SP1, for example, the first-first sub-pixel SP1a. The second signal wiring TL2 may be electrically connected to the first electrode CEL of the remaining first sub-pixel SP1 of the pair of first sub-pixels SP1, for example, the first-second sub-pixel SP1b.

The third signal wiring TL3 may be disposed at one side of the pair of second sub-pixels SP2, and the fourth signal wiring TL4 may be disposed at another side of the pair of second sub-pixels SP2. For example, the third signal wiring TL3 may be disposed neighboring the second signal wiring TL2. The third signal wiring TL3 may be electrically connected to the first electrode CE1 of one of the second sub-pixels SP2 of the pair of second sub-pixels SP2, for example, the second-first sub-pixel SP2a. The fourth signal wiring TL4 may be electrically connected to the first electrode CE1 of the remaining second sub-pixel SP2 of the pair of second sub-pixels SP2, for example, the second-second sub-pixel SP2b.

The fifth signal wiring TL5 may be disposed at one side of the pair of third sub-pixels SP3, and the sixth signal wiring TL6 may be disposed at another side of the pair of third sub-pixels SP3. For example, the fifth signal wiring TL5 may be disposed neighboring the fourth signal wiring TL4. The sixth signal wiring TL6 may be disposed neighboring the first signal wiring TL1 connected to the neighboring pixel PX. The fifth signal wiring TL5 may be electrically connected to the first electrode CE1 of one of the third sub-pixels SP3 of the pair of third sub-pixels SP3, for example, the third-first sub-pixel SP3a. The sixth signal wiring TL6 may be electrically connected to the first electrode CE1 of the remaining third sub-pixel SP3 of the pair of third sub-pixels SP3, for example, the third-second sub-pixel SP3b.

The plurality of signal wirings TL may be configured with a conductive material. For example, the plurality of signal wirings TL may be configured with a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the embodiments of the present disclosure are not limited thereto. As another example, the plurality of signal wirings TL may be formed of a multilayer structure of conductive material. For example, the plurality of signal wirings TL may be configured in a multilayer structure of titanium (Ti)/aluminum (Al)/titanium (Ti)/indium tin oxide (ITO), but the embodiments of the present disclosure are not limited thereto.

The plurality of communication wirings NLs may be disposed in an area between the plurality of pixels PX. The plurality of communication lines NLs may be disposed to extend in the row direction in the area between the plurality of pixels PX. The plurality of communication wirings NLs may be disposed in an area between the plurality of second electrodes CE2s and may not overlap with the plurality of second electrodes CE2s. For example, the plurality of communication wirings NL may be wirings used for short-range communication such as Near Field Communication (NFC). The plurality of communication wirings NL may function as antennas. For example, the plurality of communication wirings NL may be a plurality of connection wirings or the like, but the embodiments of the present disclosure are not limited thereto.

According to the present disclosure, the bank BNK may be disposed in each of the plurality of sub-pixels. A plurality of banks BNK may be structures on which a plurality of light-emitting elements ED are mounted. The plurality of banks BNK can guide the positions of the plurality of light-emitting elements ED in a transfer process during which the plurality of light-emitting elements ED are transferred to the display device 100. In a transfer process of a plurality of light-emitting elements ED, a plurality of light-emitting elements ED may be transferred onto a plurality of banks BNK. The plurality of banks BNK may be bank patterns or structures, but the embodiments of the present disclosure are not limited thereto.

The bank BNK of the first sub-pixel SP1, the bank BNK of the second sub-pixel SP2, and the bank BNK of the third sub-pixel SP3 may be disposed spaced apart from each other. The bank BNK of the first sub-pixel SP1, the bank BNK of the second sub-pixel SP2, and the bank BNK of the third sub-pixel SP3 may be configured to be separated from each other. Accordingly, the banks BNK of the first sub-pixel SP1, the second sub-pixel SP2, and the third sub-pixel SP3 to which different types of light-emitting elements ED are transferred can be easily identified.

The bank BNK of the first-first sub-pixel SP1a and the bank BNK of the first-second sub-pixel SP1b may be connected to each other or may be formed to be spaced apart or separated from each other. For example, depending on the consideration of design requirements and the like of the transfer process, the bank BNK of the first-first sub-pixel SP1a and the bank BNK of the first-second sub-pixel SP1b in which the light-emitting elements ED of the same type are disposed may be connected to each other, or may be spaced apart or separated from each other. And, the bank BNK of the second-first sub-pixel SP2a and the bank BNK of the second-second sub-pixel SP2b may be connected to each other, or may be formed to be spaced apart or separated from each other. The bank BNK of the third-first sub-pixel SP3a and the bank BNK of the third-second sub-pixel SP3b may be connected to each other or may be formed to be spaced apart or separated from each other. Accordingly, the banks BNK of the pair of first sub-pixels SP1, the banks BNK of the pair of second sub-pixels SP2, and the banks BNK of the pair of third sub-pixels SP3 can be formed in various ways, and so the embodiments of the present disclosure are not limited thereto.

For example, the plurality of banks BNK may be configured with an organic insulating material. The plurality of banks BNK may be configured in a single-layer or multi-layer structure of organic insulating material. For example, the plurality of banks BNK may be configured with a photo resist, polyimide (PI), or acrylic-based material, or the like, but the embodiments of the present disclosure are not limited thereto.

The first electrode CE1 may be disposed on each of the plurality of sub-pixels. The first electrode CE1 may be disposed on the bank BNK. The first electrode CE1 may be electrically connected to one of the plurality of signal wirings TL. At least a portion of the first electrode CE1 may extend outside of the bank BNK to be electrically connected to a signal wiring TL closest to the first electrode CE1. For example, a portion of the first electrode CE1 of the first-first sub-pixel SP1a may extend to one side area of the first-first sub-pixel SP1a to be electrically connected to the first signal wiring TL1, and a portion of the first electrode CE1 of the first-second sub-pixel SP1b may extend to another side area of the first-second sub-pixel SP1b to be electrically connected to the second signal wiring TL2. A portion of the first electrode CE1 of the second-first sub-pixel SP2a may extend to one side area of the second-first sub-pixel SP2a to be electrically connected to the third signal wiring TL3, and a portion of the first electrode CEL of the second-second sub-pixel SP2b may extend to another side area of the second-second sub-pixel SP2b to be electrically connected to the fourth signal wiring TL4. A portion of the first electrode CE1 of the third-first sub-pixel SP3a may extend to one side area of the third-first sub-pixel SP3a to be electrically connected to the fifth signal wiring TL5, and a portion of the first electrode CE1 of the third-second sub-pixel SP3b may extend to another side area of the third-second sub-pixel SP3b to be electrically connected to the sixth signal wiring TL6.

The first electrode CE1 may be electrically connected to the anode electrode 134 of the light-emitting element ED to transmit the anode voltage from the pixel driving circuit PD to the light-emitting element ED through the signal wiring TL. To the first electrode CE1 of each of the plurality of sub-pixels, a different voltage may be applied depending on the image to be displayed. For example, a different voltage may be applied to the first electrode CE1 of each of the plurality of sub-pixels. By this, the first electrode CE1 may be a pixel electrode, and the embodiments of the present disclosure are not limited thereto.

The first electrode CE1 may be configured with a conductive material. For example, the first electrode CE1 may be configured as one body with a plurality of signal wirings TL. For example, the first electrode CE1 may be configured with the same conductive material as the plurality of signal wirings TL, but the embodiments of the present disclosure are not limited thereto.

The light-emitting element ED may be disposed in each of the plurality of sub-pixels. The plurality of light-emitting elements ED may be any one of a light-emitting diode LED and a micro light-emitting diode micro LED, but the embodiments of the present disclosure are not limited thereto. The plurality of light-emitting elements ED may be disposed on the bank BNK and the first electrode CE1. The plurality of light-emitting elements ED may be disposed on the first electrode CE1 to be electrically connected to the first electrode CE1. Therefore, the light-emitting element ED can emit light by receiving an anode voltage from the pixel driving circuit PD through the signal wiring TL and the first electrode CE1.

The plurality of light-emitting elements ED may include a first light-emitting element 130, a second light-emitting element 140, and a third light-emitting element 150. The first light-emitting element 130 may be disposed in the first sub-pixel SP1. The second light-emitting element 140 may be disposed in the second sub-pixel SP2. The third light-emitting element 150 may be disposed in the third sub-pixel SP3. For example, one of the first light-emitting element 130, the second light-emitting element 140, and the third light-emitting element 150 may be a red light-emitting element, another thereof may be a green light-emitting element, and the remaining one thereof may be blue light-emitting elements, but the embodiments of the present disclosure are not limited thereto. Accordingly, by combining red light, green light, and blue light emitted from the plurality of light-emitting elements ED, light of various colors, including white, can be implemented. The types of the plurality of light-emitting elements ED are given only as an example, and the embodiments of the present disclosure are not limited thereto.

The first light-emitting element 130 may include a first-first light-emitting element 130a disposed in the first-first sub-pixel SP1a and a first-second light-emitting element 130b disposed in the first-second sub-pixel SP1b. The second light-emitting element 140 may include a second-first light-emitting element 140a disposed in the second-first sub-pixel SP2a and a second-second light-emitting element 140b disposed in the second-second sub-pixel SP2b. The third light-emitting element 150 may include a third-first light-emitting element 150a disposed in the third-first sub-pixel SP3a and a third-second light-emitting element 150b disposed in the third-second sub-pixel SP3b.

Referring to FIGS. 5, 6, 7, and 9 together, the second electrode CE2 may be disposed on each of the plurality of sub-pixels. The second electrode CE2 may be disposed on the light-emitting element ED. The second electrode CE2 may be electrically connected to the pixel driving circuit PD through a plurality of contact electrodes CCE.

For example, the second electrode CE2 may be electrically connected to the cathode electrode 135 of the light-emitting element ED to transmit the cathode voltage from the pixel driving circuit PD to the light-emitting element ED. The same cathode voltage may be applied to the second electrode CE2 of each of the plurality of sub-pixels. For example, the same voltage may be applied to the second electrode CE2 of each of the plurality of sub-pixels and the cathode electrode 135 of the light-emitting element ED. By this, the second electrode CE2 may be a common electrode, but the embodiments of the present disclosure are not limited thereto.

At least some of the plurality of sub-pixels may share the second electrode CE2 with each other. At least some of the second electrodes CE2 of the plurality of respective sub-pixels may be electrically connected to each other. As the same voltage is applied to the second electrodes CE2, the second electrode CE2 can be shared to be used for at least some sub-pixels. For example, the second electrodes CE2 of at least some of the pixels PX among the plurality of pixels PX disposed in the same row may be connected to each other. For example, one second electrode CE2 may be disposed on a plurality of pixels PX. One second electrode CE2 may be disposed for every n sub-pixels.

For example, some of the second electrodes CE2 of the plurality of respective sub-pixels may be disposed to be spaced apart from or separated from each other. For example, the second electrode CE2 connected to the pixels PX of the nth row and the second electrode CE2 connected to the pixels PX of the n+1th row may be disposed to be spaced apart from each other or separated from each other. For example, the plurality of second electrodes CE2 may be disposed to be spaced apart from each other with a plurality of communication wirings NL interposed and extending therebetween in the row direction. Thus, the number of the plurality of sub-pixels can be greater than the number of the plurality of second electrodes CE2. As another example, all of the second electrodes CE2 of a plurality of sub-pixels may be connected to each other so that only one second electrode CE2 is placed on the substrate 110, but the embodiments of the present disclosure are not limited thereto.

The plurality of second electrodes CE2 may be configured with a transparent conductive material, but the embodiments of the present disclosure are not limited thereto. The plurality of second electrodes CE2 may be configured with a transparent conductive material, so that light emitted from the light-emitting element ED can be directed toward the upper side of the second electrodes CE2. For example, the second electrode CE2 may be configured with a transparent conductive material such as indium tin oxide (ITO), indium zinc oxide (IZO), indium gallium zinc oxide (IGZO), or the like, but the embodiments of the present disclosure are not limited thereto.

The plurality of contact electrodes CCE may be disposed on the substrate 110. For example, the plurality of contact electrodes CCE may be disposed to be spaced apart from the plurality of banks BNK and the plurality of signal wirings TL. Each of the plurality of second electrodes CE2 may overlap with at least one contact electrode CCE. For example, one second electrode CE2 may overlap with the plurality of contact electrodes CCE.

For example, a plurality of contact electrodes CCE may be electrically connected to a plurality of second electrodes CE2. The plurality of contact electrodes CCE may be disposed between the substrate 110 and the plurality of second electrodes CE2 to transmit the cathode voltage from the pixel driving circuit PD to the second electrodes CE2.

For example, in a case where a micro LED is used as the light-emitting element ED, a plurality of micro LEDs may be formed on a wafer, and the micro LEDs may be transferred to the substrate 110 of the display device 100 to manufacture the display device 100. In the process of transferring a plurality of light-emitting elements ED having a microscopic size from the wafer to the substrate 110, various defects may be formed. For example, in some sub-pixels, a non-transfer defect may occur in which the light-emitting element ED is not transferred, and in other some sub-pixels, a defect may occur in which the light-emitting element ED is transferred outside the predetermined position due to an alignment error. Additionally, although the transfer process has been performed normally, the transferred light-emitting element ED itself may be defective. Therefore, taking into account the defects produced during the transfer process of the plurality of light-emitting elements ED, a plurality of light-emitting elements ED of the same type may be transferred to one sub-pixel. Lighting tests may be performed on the plurality of light-emitting elements ED, and only one light-emitting element ED that is ultimately determined to be normal may be used.

For example, the first-first light-emitting element 130a and the first-second light-emitting element 130b may be transferred together to one pixel PX and may be tested to find whether they are defective or not. If both the first-first light-emitting element 130a and the first-second light-emitting element 130b are determined to be normal, the first-first light-emitting element 130a may be used, and the first-second light-emitting element 130b may not be used. As another example, if the first-second light-emitting element 130b among the first-first light-emitting element 130a and the first-second light-emitting element 130b is determined to be normal, the first-first light-emitting element 130a may not be used and the first-second light-emitting element 130b may be used. Therefore, even if a plurality of light-emitting elements ED of the same type are transferred to one pixel PX, one light-emitting element ED can be used ultimately.

Accordingly, one of the pair of light-emitting elements ED may be a main or primary light-emitting element ED, and the other light-emitting element ED thereof may be a redundant light-emitting element ED. The redundant light-emitting element ED may be a spare light-emitting element ED that has been transferred to prepare for failure of the main light-emitting element ED. In case of the failure of the main light-emitting element ED, the redundant light-emitting element ED can be used as a replacement for it. Therefore, by transferring the main light-emitting element ED and the redundant light-emitting element ED together to one pixel PX, the deterioration of display quality due to defects in the main light-emitting element ED and the redundant light-emitting element ED can be minimized.

For example, the first-first light-emitting element 130a, the second-first light-emitting element 140a, and the third-first light-emitting element 150a transferred to one pixel PX may be used as main light-emitting elements ED, while the first-second light-emitting element 130b, the second-second light-emitting element 140b, and the third-second light-emitting element 150b may be used as redundant light-emitting elements ED.

FIG. 8 is a cross-sectional view of a display device according to an embodiment of the present disclosure. FIG. 9 is a cross-sectional view of a display device according to an embodiment of the present disclosure. For example, FIG. 8 is a cross-sectional view of the display area AA, the first non-display area NA, the bending area BA, and the second non-display area NA2. For example, FIG. 9 is a cross-sectional view of a display area including one sub-pixel SP1. Meanwhile, for convenience of illustration, the line VIII-VIII′ in FIG. 3 is illustrated as not overlapping with the driving wiring VL and the link wiring LL, but the line VIII-VIII′ in FIG. 3 is intended to indicate the same position as the adjacent driving wiring VL and link wiring LL.

Referring to FIG. 8, in the remaining area of the substrate 110 except the bending area BA, a first buffer layer 111a and a second buffer layer 111b may be disposed.

The first buffer layer 111a and the second buffer layer 111b may be disposed in the display area AA, the first non-display area NA1, and the second non-display area NA2. The first buffer layer 111a and the second buffer layer 111b may reduce the penetration of moisture or impurities through the substrate 110. The first buffer layer 111a and the second buffer layer 111b may be configured with an inorganic insulating material. For example, the first buffer layer 111a and the second buffer layer 111b may be configured in a single-layer or multi-layer structure of silicon oxide (SiOx) or silicon nitride (SiNx), but the embodiments of the present disclosure are not limited thereto.

For example, a portion of the first buffer layer 111a and the second buffer layer 111b on the bending area BA may be removed. The upper surface of the substrate 110 located in the bending area BA may be exposed from the first buffer layer 111a and the second buffer layer 111b. By removing the first buffer layer 111a and the second buffer layer 111b configured with an inorganic insulating material from the bending area BA, it is possible to minimize the cracks that may be produced in the first buffer layer 111a and the second buffer layer 111b when being bent.

Between the first buffer layer 111a and the second buffer layer 111b a plurality of alignment keys MK may be disposed. The plurality of alignment keys MK may be configured to identify the position of the pixel driving circuit PD during the manufacturing process of the display device 1000. For example, the plurality of alignment keys MK may be configured to align the position of the pixel driving circuit PD transferred on the adhesive layer 112. As another example, the plurality of alignment keys MK may be omitted. The adhesive layer 112 may be a substrate adhesive layer 112.

The substrate adhesive layer 112 may be disposed on the second buffer layer 111b. The substrate adhesive layer 112 may be disposed in the display area AA, the first non-display area NA1, the bending area BA, and the second non-display area NA2. As another example, at least a portion of the substrate adhesive layer 112 may be removed from the non-display area NA including the bending area BA. For example, the substrate adhesive layer 112 may be configured with any one of an adhesive polymer, an epoxy resin, a UV-curable resin, a polyimide series, an acrylate series, a urethane series, and a polydimethylsiloxane (PDMS), but the embodiments of the present disclosure are not limited thereto.

On the substrate adhesive layer 112 in the display area AA the pixel driving circuit PD may be disposed. In a case where the pixel driving circuit PD is implemented with a driving driver, the driving driver may be mounted on the substrate adhesive layer 112 by a transfer process, but the embodiments of the present disclosure are not limited thereto.

On the substrate adhesive layer 112 and the pixel driving circuit PD a first protective layer 113a and a second protective layer 113b may be disposed. The first protective layer 113a and the second protective layer 113b may be disposed to surround the side surface of the pixel driving circuit PD, but the embodiments of the present disclosure are not limited thereto. For example, the second protective layer 113b may be disposed to cover at least a portion of the upper surface of the pixel driving circuit PD. For example, at least one of the first protective layer 113a and the second protective layer 113b disposed on the bending area BA may be omitted. For example, the first protective layer 113a may be disposed entirely in the display area AA and the non-display area NA, and the second protective layer 113b may be disposed in part in the display area AA, the first non-display area NA1, and the second non-display area NA2. For example, a portion of the second protective layer 113b in the bending area BA may be removed. However, the embodiments of the present disclosure are not limited thereto.

The first protective layer 113a and the second protective layer 113b may be configured with an organic insulating material, but the embodiments of the present disclosure are not limited thereto. For example, the first protective layer 113a and the second protective layer 113b may be configured with a photo resist, polyimide (PI), or photo acryl-based material, or the like, but the embodiments of the present disclosure are not limited thereto. For example, the first protective layer 113a and the second protective layer 113b may be an overcoating layer or an insulating layer, but the embodiments of the present disclosure are not limited thereto.

According to the present disclosure, on the second protective layer 113b in the display area AA a plurality of first connection wirings 121 may be disposed. The plurality of first connection wirings 121 may be wirings for electrically connecting the pixel driving circuit PD with another component. For example, a pixel driving circuit PD may be electrically connected to the plurality of signal wirings TL, the plurality of contact electrodes CCE and the like through the plurality of first connection wirings 121. For example, the plurality of first connection wirings 121 may include a first-first connection wiring 121a, a first-second connection wiring 121b, a first-third connection wiring 121c, and a first-fourth connection wiring 121d, but the embodiments of the present disclosure are not limited thereto.

For example, a plurality of first-first connection wirings 121a may be disposed on the second protective layer 113b. The plurality of first-first connection wirings 121a may be electrically connected to the pixel driving circuit PD. The plurality of first-first connection wirings 121a can transmit a voltage output from the pixel driving circuit PD to the first electrode CE1 or the second electrode CE2.

For example, on the second protective layer 113b a third protective layer 114 may be disposed. The protective layer 114 may be disposed entirely in the display area AA and the non-display area NA. In the bending area BA, the third protective layer 114 may cover or surround the side surface of the second protective layer 113b and the upper surface of the first protective layer 113a. The third protective layer 114 may be configured with an organic insulating material. For example, the third protective layer 114 may be configured with a photo resist, polyimide (PI), or photo acryl-based material, or the like, but the embodiments of the present disclosure are not limited thereto. For example, the first protective layer 113a, the second protective layer 113b, and the third protective layer 114 may be configured with the same material, but the embodiments of the present disclosure are not limited thereto.

On the third protective layer 114 a plurality of first-second connection wirings 121b may be disposed. The plurality of first-second connection wirings 121b may be connected to or directly connected to the pixel driving circuit PD. For example, a portion of the first-second connection wiring 121b may be directly connected to the pixel driving circuit PD through the contact hole in the third protective layer 114. Another portion of the first-second connection wiring 121b may be electrically connected to the first-first connection wiring 121a through the contact hole in the 3rd protective layer 114. However, the embodiments of the present disclosure are not limited thereto. The voltage output from the pixel driving circuit PD may be transmitted to the first electrode CE1 or the second electrode CE2 through the plurality of first-second connection wirings 121b and another connection wiring.

On the plurality of first-second connection wirings 121b a first insulating layer 115a may be disposed. The first insulating layer 115a may be disposed entirely in the display area AA and the non-display area NA, but the embodiments of the present disclosure are not limited thereto. The first insulating layer 115a may be configured with an organic insulating material, but the embodiments of the present disclosure are not limited thereto. For example, the first insulating layer 115a may be configured with a photo resist, polyimide (PI), or photo acryl-based material, or the like, but the embodiments of the present disclosure are not limited thereto.

On the first insulating layer 115a a plurality of first-third connection wirings 121c may be disposed. The plurality of first-third connection wirings 121c may be electrically connected to the plurality of first-second connection wirings 121b. For example, the first-third connection wiring 121c may be electrically connected to the first-second connection wiring 121b through the contact hole in the first insulating layer 115a.

On the plurality of first-third connection wirings 121c a second insulating layer 115b may be disposed. The second insulating layer 115b may be disposed in the remaining area except the bending area BA, but the embodiments of the present disclosure are not limited thereto. The second insulating layer 115b may be disposed in the display area AA, the first non-display area NA1, and the second non-display area NA2, but the embodiments of the present disclosure are not limited thereto. For example, a portion of the second insulating layer 115b disposed in the bending area BA may be removed. The second insulating layer 115b may be configured with an organic insulating material, but the embodiments of the present disclosure are not limited thereto. For example, the second insulating layer 115b may be configured with a photo resist, polyimide (PI), or photo acryl-based material, or the like, but the embodiments of the present disclosure are not limited thereto.

On the second insulating layer 115b, a plurality of first-fourth connection wirings 121d may be disposed. The plurality of first-fourth connection wirings 121d may be electrically connected to the plurality of first-third connection wirings 121c. For example, the first-fourth connection wiring 121d may be electrically connected to the first-third connection wiring 121c through the contact hole in the second insulating layer 115b.

According to the present disclosure, on the second protective layer 113b in the non-display area NA a plurality of second connection wirings 122 may be disposed. The plurality of second connection wirings 122 may be wirings for transmitting, to the pixel driving circuit PD in the display area AA, signals transmitted from the flexible circuit board (or flexible film) 157 and the printed circuit board 160 (see FIG. 1) to the pad part PAD. For example, the plurality of second connection wirings 122 may be electrically connected to the plurality of pad electrodes PE to receive signals from the flexible circuit board (or flexible film) 157 and the printed circuit board.

For example, the plurality of second connection wirings 122 may extend from the pad part PAD toward the display area AA to transmit signals to the wirings of the display area AA. In this case, the plurality of second connection wirings 122 may function as the link wirings LL. The plurality of second connection wirings 122 may include a second-first connection wiring 122a, a second-second connection wiring 122b, a second-third connection wiring 122c, and a second-fourth connection wiring 122d.

On the second protective layer 113b a plurality of second-first connection wirings 122a may be disposed. The plurality of second-first connection wirings 122a may extend from the second non-display area NA2 to the bending area BA and the first non-display area NA1. The plurality of second-first connection wirings 122a may transmit, to the pixel driving circuit PD of the display area AA, signals transmitted from the flexible circuit board (or flexible film) 157 and the printed circuit board to the pad part PAD.

On the third protective layer 114, a plurality of second-second connection wirings 122b may be disposed. The plurality of second-second connection wirings 122b may be disposed in the second non-display area NA2. The second-second connection wiring 122b may be electrically connected to the second-first connection wiring 122a through the contact hole in the third protective layer 114. Accordingly, signals from the flexible circuit board (or flexible film) 157 and the printed circuit board can be transmitted to the second-first connection wiring 122a through the second-second connection wiring 122b.

On the first insulating layer 115a, the second-third connection wiring 122c may be disposed. The second-third connection wiring 122c may be disposed in the second non-display area NA2. The second-third connection wiring 122c may be electrically connected to the second-second connection wiring 122b through the contact hole in the first insulating layer 115a. Accordingly, signals from the flexible circuit board (or flexible film) 157 and the printed circuit board can be transmitted to the second-first connection wiring 122a through the second-third connection wiring 122c and the second-second connection wiring 122b.

On the second insulating layer 115b, the second-fourth connection wiring 122d may be disposed. The second-fourth connection wiring 122d may be disposed in the second non-display area NA2. The second-fourth connection wiring 122d may be electrically connected to the second-third connection wiring 122c through the contact hole in the second insulating layer 115b. Accordingly, signals from the flexible film (FF) and the printed circuit board can be transmitted to the second-first connection wiring 122a through the second-fourth connection wiring 122d, the second-third connection wiring 122c and the second-second connection wiring 122b.

The plurality of first connection wirings 121 and the plurality of second connection wirings 122 may be formed with any one of various conductive materials used in the display area AA or a conductive material having excellent ductility. For example, the second connection wiring whose portion is disposed in the bending area may be configured with a conductive material having excellent ductility, such as gold Au, silver Ag, aluminum Al or the like, but the embodiments of the present disclosure are not limited thereto. As another example, the plurality of first connection wiring 121 and the plurality of second connection wiring 122 may be configured with molybdenum (Mo), chromium (Cr), titanium (Ti), nickel (Ni), neodymium (Nd), copper (Cu), and an alloy of silver (Ag) and magnesium (Mg), or any alloy thereof, but the embodiments of the present disclosure are not limited thereto.

On a plurality of first connection wirings 121 and a plurality of second connection wirings 122, the third insulating layer 115c may be disposed. The third insulating layer 115c may be disposed in the remaining area except the bending area BA, but the embodiments of the present disclosure are not limited thereto. The third insulating layer 115c may be disposed in the display area AA, the first non-display area NA1, and the second non-display area NA2. A portion of the third insulating layer 115c in the bending area BA may be removed. The third insulating layer 115c may be configured with an organic insulating material, but the embodiments of the present disclosure are not limited thereto. For example, the third insulating layer 115c may be configured with a photo resist, polyimide (PI), or photo acryl-based material, or the like, but the embodiments of the present disclosure are not limited thereto.

On the third insulating layer 115c in the display area AA, a plurality of banks BNK may be disposed. The plurality of banks BNK may be disposed to overlap with each of the plurality of sub-pixels. On the upper side of each of the plurality of banks BNK one or more light-emitting elements ED of the same kind may be disposed.

On the third insulating layer 115c in the display area AA, a plurality of signal wirings TL may be disposed. The plurality of signal wirings TL may be disposed in the area between the plurality of banks BNK. For example, the plurality of signal wirings TL may be disposed adjacent to any one of the plurality of banks BNK.

On the third insulating layer 115c in the display area AA, a plurality of contact electrodes CCE can be disposed. The plurality of contact electrodes CCE may supply the cathode voltage from the pixel driving circuit PD to the second electrode CE2.

On the bank BNK, the first electrode CE1 may be disposed. For example, the first electrode CE1 may be disposed to extend from the adjacent signal wiring TL toward the upper side of the bank BNK. The first electrode CE1 may be disposed on the upper surface of the bank BNK and on the side surface of the bank BNK. For example, the first electrode CE1 may be disposed to extend from the signal wiring TL on the upper surface of the third insulating layer 115c to the side surface of the bank BNK and the upper surface of the bank BNK.

Referring to FIG. 9, the first electrode CE1 may be configured with a plurality of conductive layers. For example, the first electrode CE1 may include a first conductive layer CE1a, a second conductive layer CE1b, a third conductive layer CE1c, and a fourth conductive layer CE1d, but the embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, each of the first conductive layer CE1a, the second conductive layer CE1b, the third conductive layer CE1c, and the fourth conductive layer CE1d may be configured with titanium (Ti), molybdenum (Mo), aluminum (Al), or titanium (Ti) and indium tin oxide (ITO), but the embodiments of the present disclosure are not limited thereto.

According to the present disclosure, among the plurality of conductive layers constituting the first electrode CE1, some of the conductive layers having good reflection efficiency may be configured as alignment keys and/or reflecting plates for aligning the light-emitting element ED. For example, among the plurality of conductive layers of the first electrode CE1, the second conductive layer CE1b may include a reflective material. For example, the second conductive layer CE1b may include aluminum (Al), but embodiments of the present disclosure are not limited thereto. Accordingly, the second conductive layer CE1b can constitute the reflecting plate. In addition, due to the high reflection efficiency of the second conductive layer CE1b, it can be easily identified during the manufacturing process, and thus the position or transfer position of the light-emitting element ED can be aligned based on the second conductive layer CE1b.

For example, in order to form the second conductive layer CE1b as the reflecting plate, the third conductive layer CE1c and the fourth conductive layer CE1d covering the second conductive layer CE1b may be partially removed or etched. For example, a portion of the third conductive layer CE1c and the fourth conductive layer CE1d disposed on the bank BNK may be removed or etched to expose the upper surface of the second conductive layer CE1b. For example, the central portion and the border portion or edge portion of the third conductive layer CE1c and the fourth conductive layer CE1d may be left, and the remaining portion may be removed, wherein the solder pattern SDP is placed on the central portion. For example, the border portion or edge portion of each of the third conductive layer CE1c configured with titanium (Ti) and the fourth conductive layer CE1d configured with indium tin oxide (ITO) may not be etched. Accordingly, it is possible to prevent other conductive layers of the first electrode CE1 from being corroded by the tetramethylammonium hydroxide (TMAH) solution used in the mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide ITO or indium zinc oxide IZO, which has good adhesion to the solder pattern SDP and has corrosion resistance and acid resistance. However, the embodiments of the present disclosure are not limited thereto.

The first conductive layer CE1a, the second conductive layer CE1b, the third conductive layer CE1c, and the fourth conductive layer CE1d can be sequentially deposited and then patterned by performing a photolithography process and an etching process, but the embodiments of the present disclosure are not limited thereto.

According to the present disclosure, the signal wiring TL, the contact electrode CCE, and the pad electrode PE disposed on the same layer as the first electrode CE1 may be configured in a multi-layer structure of conductive materials, but the embodiments of the present disclosure are not limited thereto. For example, the signal wiring TL, contact electrode CCE, and pad electrode PE may be formed in a multi-layer structure of indium tin oxide (ITO)/titanium (Ti)/aluminum (Al)/titanium (Ti), but the embodiments of the present disclosure are not limited thereto.

According to the present disclosure, the solder pattern SDP may be disposed on the first electrode CE1 in each of the plurality of sub-pixels. The solder pattern SDP can electrically connect the first electrode CE1 with the light-emitting element ED by bonding the light-emitting element ED to the first electrode CE1. The first electrode CE1 and the anode electrode 134 of the light-emitting element ED may be electrically connected through eutectic bonding using the solder pattern SDP, but the embodiments of the present disclosure are not limited thereto. For example, in a case where the solder pattern SDP is configured with indium (In) and the anode electrode (134) of the light-emitting element ED is configured with gold (Au), the solder pattern SDP and the anode electrode 134 may be joined by applying heat and pressure during the transfer process of the light-emitting element ED. Through the eutectic bonding, the light-emitting element ED can be bonded to the solder pattern SDP and the first electrode CE1 without a separate adhesive material. For example, the solder pattern SDP may be configured with indium (In), tin (Sn) or alloys thereof, but embodiments of the present disclosure are not limited thereto. For example, the solder pattern SDP may be a bonding pad or a joining pad, but the embodiments of the present disclosure are not limited thereto.

According to the present disclosure, on the plurality of signal wirings TL, the plurality of first electrodes CE1, the plurality of contact electrodes CCE, and the third insulating layer 115c a passivation layer 116 may be disposed. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE in the second non-display area NA2 may be removed. The passivation layer 116 may be disposed to cover the remaining area except the bending area BA, the plurality of pad electrodes PE, and the area where the solder pattern SDP is disposed, thus capable of reducing the penetration of moisture or impurities into the light-emitting element ED. For example, the passivation layer 116 may be configured in a single-layer or multi-layer structure of silicon oxide (SiOx) or silicon nitride (SiNx), but the embodiments of the present disclosure are not limited thereto. For example, the passivation layer 116 may be a protective layer or an insulating layer, but the embodiments of the present disclosure are not limited thereto. For example, the passivation layer 116 may include a hole through which the solder pattern SDP is exposed.

In each of the plurality of sub-pixels, the light-emitting element ED may be disposed on the solder pattern SDP. In the first sub-pixel SP1 the first light-emitting element 130 may be disposed. In the second sub-pixel SP2 the second light-emitting element 140 may be disposed. In the third sub-pixel SP3 the third light-emitting element 150 may be disposed.

The light-emitting element ED may be formed on a silicon wafer by a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like, but the embodiments of the present disclosure are not limited thereto.

Referring to FIG. 9, the first light-emitting element 130 may include the anode electrode 134, a first semiconductor layer 131, an active layer 132, a second semiconductor layer 133, a cathode electrode 135, and a sealing film 136, but the embodiments of the present disclosure are not limited thereto. For example, the first light-emitting element 130 may not include the sealing film 136.

On a solder pattern SDP, the first semiconductor layer 131 may be disposed. On the first semiconductor layer 131 the second semiconductor layer 133 may be disposed.

For example, one of the first semiconductor layer 131 and the second semiconductor layer 133 may be implemented as a compound semiconductor of group III-V, group II-VI, or the like, and may be doped with an impurity or dopant. For example, one of the first semiconductor layer 131 and the second semiconductor layer 133 may be a semiconductor layer doped with an n-type impurity, and the other thereof may be a semiconductor layer doped with a p-type impurity, but the embodiments of the present disclosure are not limited thereto. For example, one of the first semiconductor layer 131 and the second semiconductor layer 133 may be a layer where an n-type or p-type impurity is doped in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto. For example, the n-type impurity may be silicon (Si), germanium (Ge), selenium (Se), carbon (C), tellurium (Te), tin (Sn), or the like, but the embodiments of the present disclosure are not limited thereto. For example, the p-type impurity may be magnesium (Mg), zinc (Zn), calcium (Ca), strontium (Sr), barium (Ba), beryllium (Be), or the like, but the embodiments of the present disclosure are not limited thereto.

For example, the first semiconductor layer 131 and the second semiconductor layer 133 may be a nitride semiconductor containing an n-type impurity and a nitride semiconductor containing a p-type impurity, respectively, but the embodiments of the present disclosure are not limited thereto. For example, the first semiconductor layer 131 may be a nitride semiconductor containing a p-type impurity, and the second semiconductor layer 133 may be a nitride semiconductor containing an n-type impurity, but the embodiments of the present disclosure are not limited thereto.

The active layer 132 may be disposed between the first semiconductor layer 131 and the second semiconductor layer 133. The active layer 132 may emit light by receiving holes and electrons from the first semiconductor layer 131 and the second semiconductor layer 133. For example, the active layer 132 may be configured in one of a single well structure, a multi-well structure, a single quantum well structure, a multi-quantum well (MQW) structure, a quantum dot structure, and a quantum wiring structure, but the embodiments of the present disclosure are not limited thereto. For example, the active layer 132 may be composed of indium gallium nitride (InGaN) or gallium nitride (GaN), but the embodiments of the present disclosure are not limited thereto.

As another example, the active layer 132 may include a multi-quantum well (MQW) structure having a well layer and a barrier layer having a higher band gap than the well layer. For example, the active layer 132 may be composed of InGaN as a well layer and an AlGaN layer as a barrier layer, but the embodiments of the present disclosure are not limited thereto.

The anode electrode 134 may be disposed between the first semiconductor layer 131 and the solder pattern SDP. For example, the anode electrode 134 may electrically connect the first semiconductor layer 131 with the first electrode CE1. The anode voltage output from the pixel driving circuit PD may be applied to the first semiconductor layer 131 through the signal wiring TL, the first electrode CE1, and the anode electrode 134. For example, the anode electrode 134 may be composed of a conductive material capable of eutectic bonding with the solder pattern SDP, but the embodiments of the present disclosure are not limited thereto. For example, the anode electrode 134 may be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or any alloy thereof, but the embodiments of the present disclosure are not limited thereto.

The cathode electrode 135 may be disposed on the second semiconductor layer 133. For example, the cathode electrode 135 may electrically connect the second semiconductor layer 133 with the second electrode CE2. The cathode voltage output from the pixel driving circuit PD may be applied to the second semiconductor layer 133 through the contact electrode CCE, the second electrode CE2, and the cathode electrode 135. The cathode electrode 135 may be composed of a transparent conductive material so that light emitted from the light-emitting element ED can be directed to the upper side of the light-emitting element ED, but the embodiments of the present disclosure are not limited thereto. For example, the cathode electrode 135 may be configured with a material such as indium tin oxide (ITO), indium zinc oxide (IZO), indium gallium zinc oxide (IGZO), or the like, but the embodiments of the present disclosure are not limited thereto.

The sealing film 136 may be disposed on at least a portion of the first semiconductor layer 131, the active layer 132, the second semiconductor layer 133, the anode electrode 134, and the cathode electrode 135. For example, the sealing film 136 may surround at least a portion of the first semiconductor layer 131, the active layer 132, the second semiconductor layer 133, the anode electrode 134, and the cathode electrode 135.

For example, the sealing film 136 may protect the first semiconductor layer 131, the active layer 132, and the second semiconductor layer 133. For example, the sealing film 136 can be disposed on the side surface of the first semiconductor layer 131, the side surface of the active layer 132, and the side surface of the second semiconductor layer 133.

For example, the sealing film 136 may be disposed on at least a portion of the anode electrode 134 and the cathode electrode 135, for example, an edge portion or a border portion or one side of the anode electrode 134 and an edge portion or a border portion or one side of the cathode electrode 135. At least a portion of the anode electrode 134 may be exposed from the sealing film 136 so that the anode electrode 134 and the solder pattern SDP can be connected to each other. For example, at least a portion of the cathode electrode 135 may be exposed from the sealing film 136 so that the cathode electrode 135 and the second electrode CE2 can be connected to each other. For example, the sealing film 136 may be configured with an insulating material such as silicon nitride (SiNx) or silicon oxide (SiOx), but the embodiments of the present disclosure are not limited thereto.

In another example, the sealing film 136 may be configured as a resin layer in which a reflective material is dispersed, but the embodiments of the present disclosure are not limited thereto. For example, the sealing film 136 may be manufactured as a reflector having various structures, but the embodiments of the present disclosure are not limited thereto. Light emitted from the active layer 132 can be reflected to the upper side by the sealing film 136, so that light extraction efficiency can be improved. For example, the sealing film 136 may be a reflective layer, but the embodiments of the present disclosure are not limited thereto.

According to the present disclosure, the light-emitting element ED is described as having a vertical structure, but the embodiments of the present disclosure are not limited thereto. For example, the light-emitting element ED may have a lateral structure or a flip chip structure.

Although the first light-emitting element 130 has been described with reference to FIG. 9, the second light-emitting element 140 and the third light-emitting element 150 may have structures substantially identical to that of the first light-emitting element 130. For example, the second light-emitting element 140 and the third light-emitting element 150 may be substantially identical to the first semiconductor layer 131, the active layer 132, the second semiconductor layer 133, the anode electrode 134, the cathode electrode 135, and the sealing film 136 of the first light-emitting element 130.

According to the present disclosure, in the display area AA, there may be disposed a first optical layer 117a surrounding a plurality of light-emitting elements ED. For example, the first optical layer 117a may be disposed to cover a plurality of light-emitting elements ED and banks BNK in the areas of a plurality of sub-pixels. For example, the first optical layer 117a may cover the bank BNK, a portion of the passivation layer 116, and a gap between a plurality of light-emitting elements ED. The first optical layer 117a may cover or be disposed between a plurality of light-emitting elements ED and between a plurality of banks BNK included in one pixel PX. For example, the first optical layers 117a may extend in a first direction (X) and be spaced apart from each other in the second direction (Y). For example, the first optical layer 117a may be disposed to surround the side portion of the bank BNK and the light-emitting element ED between the passivation layer 116 and the second electrode CE2, but the embodiments of the present disclosure are not limited thereto. For example, the first optical layer 117a may be a diffusion layer or a sidewall diffusion layer, but the embodiments of the present disclosure are not limited thereto.

The first optical layer 117a may include an organic insulating material having fine particles dispersed therein, but the embodiments of the present disclosure are not limited thereto. For example, the first optical layer 117a may be composed of siloxane having fine particles such as titanium dioxide (TiO₂) particles dispersed therein, but the embodiments of the present disclosure are not limited thereto. Light from the plurality of light-emitting elements ED may be scattered by fine particles dispersed in the first optical layer 117a and emitted to the outside of the display device 1000. Accordingly, the first optical layer 117a can improve the extraction efficiency of light emitted from the plurality of light-emitting elements ED.

For example, the first optical layer 117a may be disposed in each of the plurality of pixels PX or may be disposed commonly for some of the pixels PX disposed in the same row, but the embodiments of the present disclosure are not limited thereto. For example, the first optical layer 117a may be disposed in each of a plurality of pixels PX or a plurality of pixels PX may share one first optical layer 117a. In another example, each of the plurality of sub-pixels may separately include a first optical layer 117a, but the embodiments of the present disclosure are not limited thereto.

According to the present disclosure, a second optical layer 117b may be disposed on the passivation layer 116 in the display area AA. For example, the second optical layer 117b may be disposed to surround the first optical layer 117a. For example, the second optical layer 117b may be in contact with a side surface of the first optical layer 117a. For example, the second optical layer 117b may be disposed in an area between a plurality of pixels PX. However, the embodiments of the present disclosure are not limited thereto. For example, the second optical layer 117b may be a diffusion layer, a diffusion layer window, a window diffusion layer, or the like, but the embodiments of the present disclosure are not limited thereto.

The second optical layer 117b may be composed of an organic insulating material, but the embodiments of the present disclosure are not limited thereto. The second optical layer 117b may be composed of the same material as the first optical layer 117a, but the embodiments of the present disclosure are not limited thereto. For example, the first optical layer 117a may include fine particles, and the second optical layer 117b may not include fine particles. For example, the second optical layer 117b may be configured with siloxane, but the embodiments of the present disclosure are not limited thereto.

For example, the thickness of the first optical layer 117a may be smaller than the thickness of the second optical layer 117b, but the embodiments of the present disclosure are not limited thereto. Accordingly, when viewed in a plan view, the area where the first optical layer 117a is disposed may include a concave portion that is recessed inward more than the upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through contact holes in the second optical layer 117b. For example, the second electrode CE2 may be disposed on a plurality of light-emitting elements ED. For example, the second electrode CE2 may include a transparent conductive oxide such as indium tin oxide (ITO) or indium zinc oxide (IZO), but the embodiments of the present disclosure are not limited thereto. For example, the second electrode CE2 may be disposed in contact with the cathode electrode 135. For example, the second electrode CE2 may overlap with the first optical layer 117a. For example, it may cover the outer plane of the first optical layer 117a.

The second electrode CE2 may extend continuously in the first direction of the substrate 110. Accordingly, it can be commonly connected to a plurality of pixels PX arranged in the first direction of the substrate 110. For example, the second electrode CE2 may be commonly connected to a plurality of pixels PX.

According to the present disclosure, the second electrode CE2 may extend continuously over the first optical layer 117a, the second optical layer 117b, and the light-emitting element ED. The area where the first optical layer 117a is disposed may include a concave portion that is recessed inward more than the upper surface of the second optical layer 117b. Accordingly, a first portion of the second electrode CE2 disposed on the first optical layer 117a is disposed along the concave portion, and thus can be disposed at a lower position than a second portion of the second electrode CE2 disposed on the second optical layer 117b.

On the second electrode CE2, a third optical layer 117c may be disposed. The third optical layer 117c may be disposed to overlap with the plurality of light-emitting elements ED and the first optical layer 117a. Since the third optical layer 117c is disposed on the second electrode CE2 and the plurality of light-emitting elements ED, it is possible to alleviate stains Mura that may occur on some of the plurality of light-emitting elements ED. For example, when transferring the plurality of light-emitting elements ED onto the substrate 110 of the display device 100, its process deviation or the like may cause the occurrence of an area where the spacings between the plurality of light-emitting elements ED are not uniform. If the spacings between the plurality of light-emitting elements ED are uneven, the emission areas of the plurality of respective light-emitting elements ED may be disposed unevenly, which may, in turn, cause stains Mura to be visible to the user. To address this, the third optical layer 117c is constructed over the plurality of light-emitting elements ED so as to be configured to uniformly diffuse light over, and thus it is possible to alleviate the phenomenon in which light emitted from some light-emitting elements ED looks like stains. Accordingly, since the light emitted from the plurality of light-emitting elements ED is evenly diffused by the third optical layer 117c and extracted to the outside of the display device 1000, the brightness uniformity of the display device 1000 can be improved.

The third optical layer 117c may be composed of an organic insulating material having fine particles dispersed therein, but the embodiments of the present disclosure are not limited thereto. For example, the third optical layer 117c may be composed of siloxane having fine particles such as titanium dioxide (TiO₂) particles dispersed therein, but the embodiments of the present disclosure are not limited thereto. For example, the third optical layer 117c may be composed of the same material as the first optical layer 117a, but the embodiments of the present disclosure are not limited thereto. For example, the third optical layer 117c may be a diffusion layer or an upper surface diffusion layer, but the embodiments of the present disclosure are not limited thereto.

The refractive index of the third optical layer 117c may range from 1.50 to 1.55. In one example, the refractive index of the third optical layer 117c may be 1.53.

According to the present disclosure, light from a plurality of light-emitting elements ED can be emitted to the outside of the display device 1000 in a state of being scattered by fine particles dispersed in the third optical layer 117c. The third optical layer 117c can evenly mix the lights emitted from the plurality of light-emitting elements ED to further improve the brightness uniformity of the display device 1000. Furthermore, the light extraction efficiency of the display device 1000 can be improved by the light being scattered by the plurality of fine particles, thereby enabling the display device 1000 to be driven at low power.

On the second electrode CE2, the first optical layer 117a, the second optical layer 117b, and the third optical layer 117c in the display area AA, there may be disposed a black matrix BM. For example, the black matrix BM may fill the contact hole in the second optical layer 117b. The black matrix BM may be formed to cover the display area AA, so that color mixing of light from a plurality of sub-pixels and external light reflection can be reduced. For example, since the black matrix BM may be disposed within the contact hole where the second electrode CE2 and the contact electrode CCE are connected to each other, light leakage between neighboring sub-pixels can be prevented.

For example, the black matrix BM may be composed of an opaque material, but the embodiments of the present disclosure are not limited thereto. For example, the black matrix BM may be an organic insulating material having black pigment or black dye added thereto, but the embodiments of the present disclosure are not limited thereto.

On the black matrix BM in the display area AA, a cover layer 118 may be disposed. The cover layer 118 can protect the configuration under the cover layer 118. For example, the cover layer 118 may be composed of an organic insulating material, but the embodiments of the present disclosure are not limited thereto. For example, the cover layer 118 may be configured with a photo resist, polyimide (PI), or photo acryl-based material, or the like, but the embodiments of the present disclosure are not limited thereto. For example, the cover layer 118 may be an overcoating layer or an insulating layer, but the embodiments of the present disclosure are not limited thereto.

On the cover layer 118, the polarizing layer 293 may be disposed via a first adhesive layer 291. On the polarizing layer 293, the cover member 155 may be disposed via a second adhesive layer 295. For example, the first adhesive layer 291 and the second adhesive layer 295 may include an optically clear adhesive (OCA), an optically clear resin (OCR), or a pressure sensitive adhesive (PSA), but the embodiments of the present disclosure are not limited thereto.

According to the present disclosure, on the third insulating layer 115c in the second non-display area NA2, the plurality of pad electrodes PE may be disposed. For example, at least a portion of the plurality of pad electrodes PE may be exposed from the passivation layer 116. For example, a plurality of pad electrodes PE may be electrically connected to the second-fourth connection wiring 122d through the contact hole in the third insulating layer 115c.

On the plurality of pad electrodes PE, an adhesive layer ACF may be disposed. The adhesive layer ACF may be an adhesive layer in which conductive balls are dispersed in an insulating material, but the embodiments of the present disclosure are not limited thereto. In a case where heat or pressure is applied to the adhesive layer ACF, the conductive balls can be electrically connected in the part where the heat or pressure is applied, thereby providing conductive property. By placing the adhesive layer ACF between a plurality of pad electrodes PE and the flexible circuit board (or flexible film) 157, the flexible circuit board (or flexible film) 157 can be attached or bonded to a plurality of pad electrodes PE. For example, the adhesive layer ACF may be an anisotropic conductive film ACF, but the embodiments of the present disclosure are not limited thereto.

On the adhesive layer ACF, the flexible circuit board (or flexible film) 157 may be disposed. The flexible circuit board (or flexible film) 157 may be electrically connected to the plurality of pad electrodes PE through the adhesive layer ACF. Accordingly, signals output from the flexible circuit board (or flexible film) 157 and the printed circuit board can be transmitted to the pixel driving circuit PD in the display area AA through the plurality of pad electrodes PE, the second-fourth connection wiring 122d, the second-third connection wiring 122c, the second-second connection wiring 122b, and the second-first connection wiring 122a.

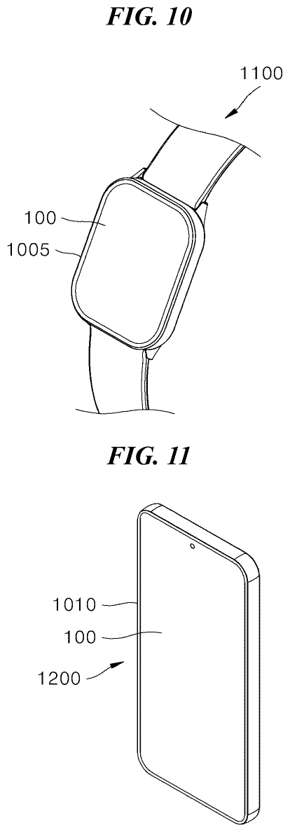

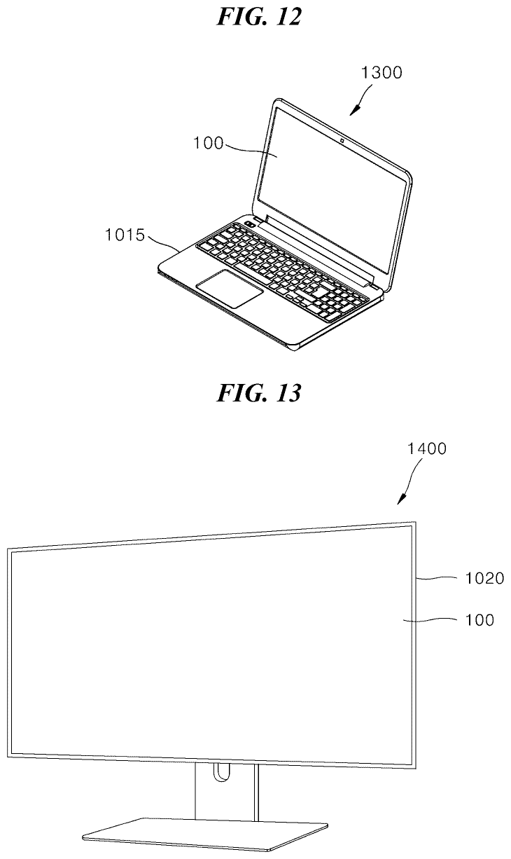

FIGS. 10 to 13 are views illustrating devices to which display devices according to embodiments of the present disclosure are applied.

Referring to FIGS. 10 to 13, the display device 1000 according to the embodiments of the present disclosure may be included in various devices or electronic devices. For example, referring to FIGS. 10 to 13, various electronic devices may include a wearable device 1100, a mobile device 1200, a notebook 1300, and a monitor or TV 1400, but the embodiments of the present disclosure are not limited thereto.

Each of the wearable device 1100, the mobile device 1200, the notebook 1300, and the monitor or TV 1400 may respectively include a case 1005, 1010, 1015, 1020, the display panel 100 and the display device 1000 according to the embodiment of the present disclosure described with reference to FIGS. 1 to 9.

For example, the display device according to the embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, home appliances, or the like.

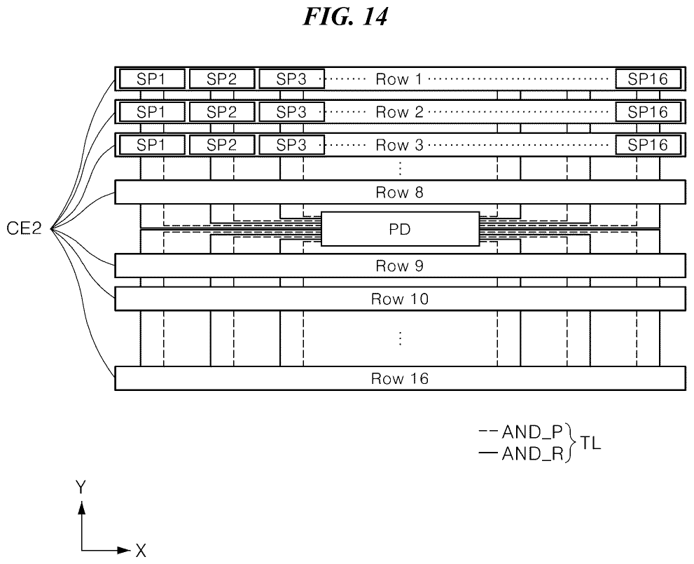

FIG. 14 is a plan view showing an area where one pixel driving circuit of a plurality of pixel driving circuits is arranged according to one embodiment.

Referring to FIGS. 3, 5 and 14 together, one pixel driving circuit PD may be electrically connected to a plurality of signal wirings TL that are electrically connected to a plurality of sub-pixels. A plurality of sub-pixels may include a plurality of light-emitting elements ED (see FIG. 3) disposed in the same column direction SP1, SP2, SP3, . . . , SP16 and the same row direction Row1, Row2, Row3, . . . , Row16.

Between the plurality of sub-pixels the plurality of signal wirings TL extending in the column direction may be disposed. The plurality of signal wirings TL may include a first line AND_P and a second line AND_R. The first line AND_P and the second line AND_R may be disposed to be spaced apart from each other in the first direction X, which is the row direction. Each of the first line AND_P and the second line AND_R may be electrically connected to a pair of sub-pixels, respectively. The pair of sub-pixels may each have a light-emitting element ED disposed thereon. One of the light-emitting elements ED may be a main light-emitting element, and the other one thereof may be a redundant light-emitting element. For example, referring to FIG. 5, the first-first light-emitting element 130a, the second-first light-emitting element 140a, and the third-first light-emitting element 150a transferred to one pixel PX may be main light-emitting elements ED. Additionally, the first-second light-emitting element 130b, the second-second light-emitting element 140b, and the third-second light-emitting element 150b may be redundant light-emitting elements ED.

The first line AND_P may correspond to a signal wiring disposed in an odd number column. For example, referring to FIGS. 5 and 14 together, the first line AND_P may correspond to a first signal wiring TL1, a third signal wiring TL3, and a fifth signal wiring TL5. The second line AND_R may correspond to a signal wiring disposed in an even number column. For example, the second line AND_R may correspond to a second signal wiring TL2, a fourth signal wiring TL4, and a sixth signal wiring TL6. The first line AND_P and the second line AND_R may be referred to as a signal wiring.

The plurality of second electrodes CE2 may be disposed to extend in the row direction. The plurality of second electrodes CE2 may each be disposed to be spaced apart from each other in the second direction Y which is the column direction.

The plurality of signal wirings TL may be radially connected with at least one pixel driving circuit PD to connect the first sub-pixel SP1 disposed at a first position in the first row Row1 and the sixteenth sub-pixel SP16 disposed at a sixteenth position opposite to the first sub-pixel SPX1 with the pixel driving circuit PD, respectively. For example, a shape in which the plurality of signal wirings TL are connected may be a rhombus shape or a letter ‘I’ shape when viewed from a plan view.

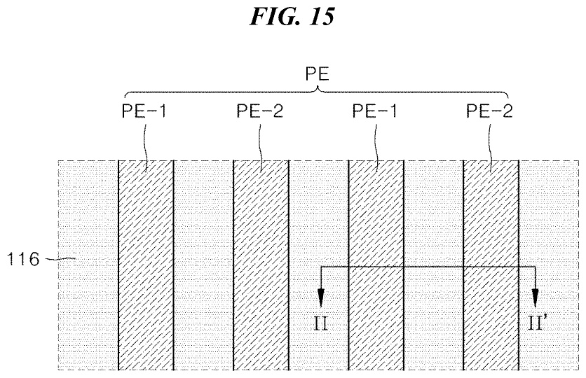

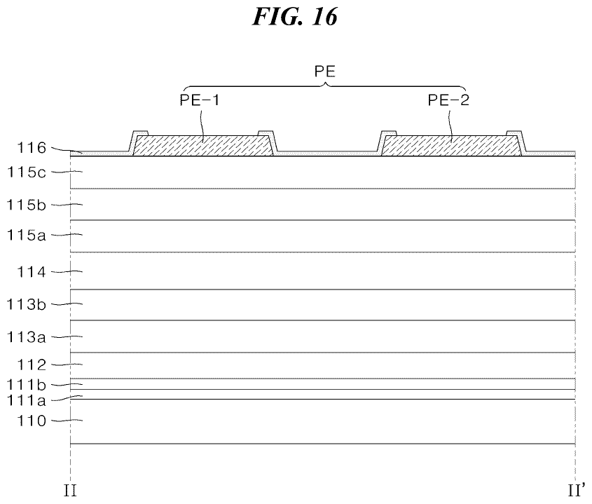

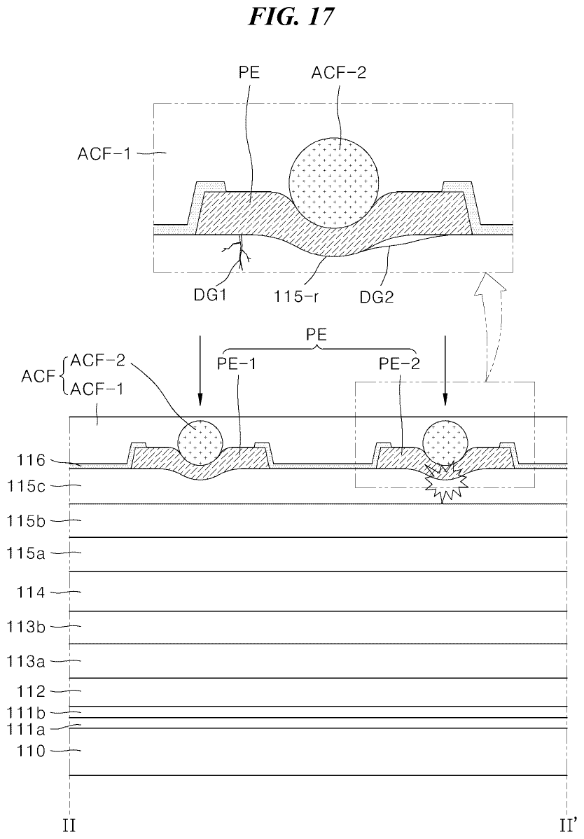

FIG. 15 is an enlarged plan view showing area ‘I’ in FIG. 2 according to the first embodiment of the present disclosure. FIG. 16 is a cross-sectional view taken along line II-II′ in FIG. 15 according to one embodiment. FIG. 17 is a cross-sectional view showing a pad electrode with an adhesive layer disposed in the upper side thereof according to one embodiment.

In FIGS. 15 to 17, the same reference symbols will be given to the same components as those described with reference to FIG. 8, and the description thereof will be simplified or omitted.

Referring to FIGS. 2, 15, and 16 together, in the second non-display area NA2 in the non-display area NA, there may be disposed the pad part PAD including a plurality of pad electrodes PE. The plurality of pad electrodes PE may be electrically connected to one or more flexible circuit boards 157. The plurality of pad electrodes PE may transmit various signals (or powers) from the printed circuit board 160 and the flexible circuit board 157 to the plurality of pixel driving circuits PD of the display area AA.

In the second non-display area NA2, there may be disposed a multilayer insulating structure disposed entirely over the display area AA and the non-display area NA. For example, the multilayer insulating structure may have a lower multilayer structure disposed in the lower side of a substrate adhesive layer 112 disposed on the substrate 110, and including a first buffer layer 111a and a second buffer layer 111b. The first buffer layer 111a and the second buffer layer 111b may include an inorganic insulating material.

In the upper side of the multilayer structure, there may be disposed an upper multilayer structure. The upper multilayer structure may include a first protective layer 113a, a second protective layer 113b, a third protective layer 114, a first insulating layer 115a, a second insulating layer 115b, and a third insulating layer 115c. Each of the layers constituting the upper multilayer structure may be configured to include an organic insulating material. However, the embodiments of the present disclosure are not limited thereto.

The plurality of pad electrodes PE may be disposed to be spaced apart from each other on the third insulating layer 115c of the upper multilayer structure.

The plurality of pad electrodes PE may have a structure in which first pad electrodes PE-1 and second pad electrodes PE-2 are disposed alternately. For example, the first pad electrode PE-1 may be an odd-numbered pad electrode, and the second pad electrode PE-2 may be an even-numbered pad electrode.

The first pad electrode PE-1 and the second pad electrode PE-2 may be configured in a multilayer structure of conductive material. For example, the first pad electrode PE-1 and the second pad electrode PE-2 may be disposed in the same layer as the signal wiring TL and the contact electrode CCE disposed in the display area AA, and may be configured in a multilayer structure of the same conductive material as them. For example, the first pad electrode PE-1 and the second pad electrode PE-2 may be formed in a multilayer structure of indium tin oxide (ITO)/titanium (Ti)/aluminum (Al)/titanium (Ti), but are not limited to these materials.

On the first pad electrode PE-1 and the second pad electrode PE-2 a passivation layer 116 may be disposed. The passivation layer 116 can prevent aluminum Al of the conductive materials of the first pad electrode PE-1 and the second pad electrode PE-2 from being exposed to a cleaning solution to be damaged. For this purpose, the passivation layer 116 may include an inorganic insulating material that is not affected by the cleaning solution. For example, the passivation layer 116 may be configured in a single-layer or multi-layer structure of silicon oxide (SiOx) or silicon nitride (SiNx); however, this is not exhaustive.

The passivation layer 116 may be partially removed to expose the upper surfaces of the first pad electrode PE-1 and the second pad electrode PE-2. The passivation layer 116 may cover the side surfaces and upper edges of each of the first pad electrode PE-1 and the second pad electrode PE-2. The passivation layer 116 may cover the third insulating layer 115c between the first pad electrode PE-1 and the second pad electrode PE-2.

Referring to FIG. 17, on the plurality of pad electrodes PE, an adhesive layer ACF may be disposed. The adhesive layer ACF may be disposed between the electrode of the flexible circuit board 157 (see FIG. 8) and the pad electrode PE to electrically connect the two structures to each other.

The adhesive layer ACF may include a configuration in which a plurality of conductive balls ACF-2 are dispersed within a binder ACF-1. The binder ACF-1 may include an insulating material having an adhesive property. The binder ACF-1 can prevent or at least reduce a likelihood of a short circuit from occurring by electrically insulating between the first pad electrode PE-1 and the second pad electrode PE-2 disposed adjacent to each other. For example, the binder ACF-1 may include a thermosetting insulating material including polyurethane, acrylic resin, or epoxy resin.

A plurality of conductive balls ACF-2 may be dispersed within the binder ACF-1. After disposing the adhesive layer ACF between the electrode of a flexible circuit board 157 (see FIG. 8) and the pad electrode PE, physical pressure is applied on the adhesive layer ACF while maintaining a high temperature, and thereby the conductive ball ACF-2 can be pressed toward the pad electrode PE, so that the pad electrode PE and the electrode of the flexible circuit board 157 can be electrically connected to each other through the conductive ball ACF-2.

The space other than the pad electrode PE in contact with the conductive ball ACF-2 can be filled with the binder ACF-1. Accordingly, electrical insulation can be maintained between the first pad electrode PE-1 and the second pad electrode PE-2 disposed adjacent to each other.

Meanwhile, the pad electrode PE is configured in a multilayer structure of a relatively hard conductive material, and the upper multilayer structure disposed in the lower side of the pad electrode PE is configured with an organic insulating material. The organic insulating material is vulnerable to physical pressure, and so may be deformed by external force.

For example, when physical pressure is applied to the adhesive layer ACF, the conductive balls ACF-2 dispersed within the adhesive layer ACF may be pressed toward the pad electrode PE disposed in the lower side. When the conductive ball ACF-2 is pressed toward the pad electrode PE, stress may be applied to the upper multilayer structure including the third insulating layer 115c in contact with the relatively hard pad electrode PE, which may cause microcracks DG1. Alternatively, the adhesion between the third insulating layer 115c and the pad electrode PE may be reduced, and their boundary surfaces may be separated from each other, resulting in a displacement DG2. The micro displacement DG2 may lead to a problematic situation where the organic insulating material is recessed.

If moisture or the like penetrates through the microcracks DG1 formed in the upper multilayer structure or if the displacement DG2 phenomenon propagates, the reliability of the entire display device may be deteriorated. For example, if the pad electrode PE is not fixed to the third insulating layer 115c and is displaced therefrom, and the displaced portion propagates, the electrical connection with the flexible circuit board 157 may not be properly established. Then, the signals output from the flexible circuit board 157 or printed circuit board may not be properly transmitted to the pixel driving circuit PD of the display area AA.

In view of the above, another embodiment of the present disclosure may include a configuration capable of preventing or at least reducing the likelihood of the microcracks DG1 or the displacement DG2 phenomenon from occurring in the upper multilayer structure by the conductive balls ACF-2 dispersed in the adhesive layer ACF.

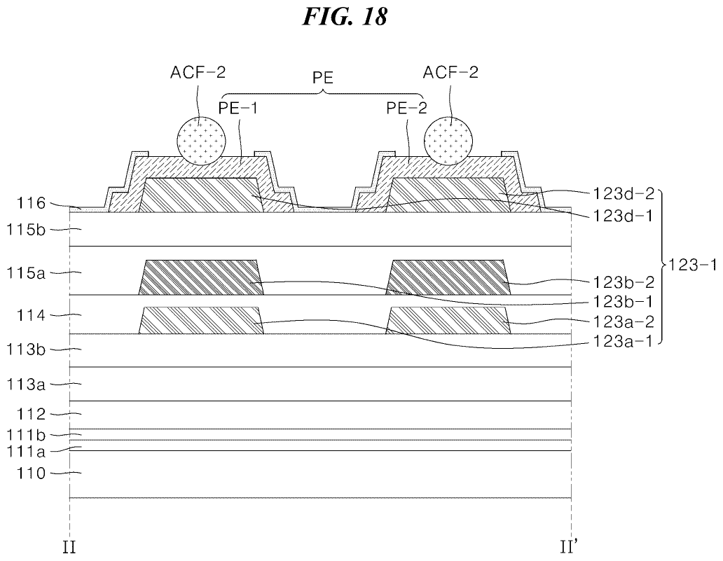

FIG. 18 is a cross-sectional view showing a pad part according to the second embodiment of the present disclosure. For example, FIG. 18 is a cross-sectional view taken along line II-II′ in FIG. 15.

In FIG. 18, the same reference symbols will be given to the same components as those described with reference to FIG. 17, and the description thereof will be simplified or omitted. Also, for convenience of explanation, only the configuration of the conductive balls ACF-2 in the adhesive layer is shown.

Referring to FIGS. 2 and 18, on the substrate 110 of the pad part PAD, a multilayer structure may be disposed. The multilayer structure may include a lower multilayer structure disposed in the lower side of the substrate adhesive layer 112, and an upper multilayer structure disposed in the upper side of the substrate adhesive layer 112.

The upper multilayer structure may include at least one or more of a first protective layer 113a, a second protective layer 113b, a third protective layer 114, a first insulating layer 115a, a second insulating layer 115b, and a third insulating layer 115c.

For example, the upper multilayer structure according to the second embodiment of the present disclosure may include a structure in which the first protective layer 113a, the second protective layer 113b, the third protective layer 114, the first insulating layer 115a, and the second insulating layer 115b are stacked. Each of the layers constituting the upper multilayer structure may include an organic insulating material.

The plurality of pad electrodes PE may be disposed to be spaced apart from each other on the second insulating layer 115b of the upper multilayer structure. The plurality of pad electrodes PE may be configured in a multilayer structure of conductive material.

In an area or areas in the upper multilayer structure which correspond(s) to an area where the pad electrode PE is disposed, one or more reinforcement patterns 123-1 may be disposed. One or more reinforcement patterns 123-1 can prevent stress from being applied to the upper multilayer structure including an organic insulating material when the conductive ball ACF-2 dispersed in the adhesive layer are pressed toward the pad electrode PE disposed in the lower side during the attachment process of the adhesive layer.

The reinforcement patterns 123-1 may be disposed to overlap with each other in the up and down direction (e.g., the vertical direction or Y-direction) in the upper multilayer structure. For example, the reinforcement patterns 123-1 may include a first reinforcement pattern 123a-1, 123a-2 disposed on the second protective layer 113b, a second reinforcement pattern 123b-1, 123b-2 disposed on the third protective layer 114, and a fourth reinforcement pattern 123d-1, 123d-2 disposed on the second insulating layer 115b. In this case, the uppermost layer of the upper multilayer structure may be the second insulating layer 115b. However, this is not exhaustive. The plurality of pad electrodes PE may be disposed on the fourth reinforcement patterns 123d-1, 123d-2. The pad electrode PE may cover both side surfaces and the upper surface of the fourth reinforcement pattern 123d-1, 123d-2.

The first reinforcement pattern 123a-1, 123a-2, the second reinforcement pattern 123b-1, 123b-2, and the fourth reinforcement pattern 123d-1, 123d-2 may be disposed respectively to overlap with each other in the up and down direction. For example, the first reinforcement pattern 123a-1, 123a-2, the second reinforcement pattern 123b-1, 123b-2, and the fourth reinforcement pattern 123d-1, 123d-2 may be disposed corresponding to the area where the pad electrode PE-1, PE-2 is disposed. Additionally, the first reinforcement pattern 123a-1, 123a-2, the second reinforcement pattern 123b-1, 123b-2, and the fourth reinforcement pattern 123d-1, 123d-2 may be disposed in different layers, respectively.

The first reinforcement pattern 123a-1, 123a-2, the second reinforcement pattern 123b-1, 123b-2, and the fourth reinforcement pattern 123d-1, 123d-2 may include the same material as the first connection wiring 121, see FIG. 8 disposed on the display area AA or the second connection wiring 122 disposed on the second non-display area NA2, and may be disposed in the same layer as one of them.

For example, the first reinforcement pattern 123a-1, 123a-2 may include the same material as the first-first connection wiring 121a and the second-first connection wiring 122a and may be disposed in the same layer as them. The second reinforcement pattern 123b-1, 123b-2 may include the same material as the first-second connection wiring 121b and the second-second connection wiring 122b and may be disposed in the same layer as them. And the fourth reinforcement pattern 123d-1, 123d-2 may include the same material as the first-fourth connection wiring 121d and the second-fourth connection wiring 122d and may be disposed in the same layer as them.

The first reinforcement pattern 123a-1, 123a-2, the second reinforcement pattern 123b-1, 123b-2, and the fourth reinforcement pattern 123d-1, 123d-2 may each have different thicknesses. The first thickness of the first reinforcement pattern 123a-1, 123a-2, the second reinforcement pattern 123b-1, 123b-2, and the fourth reinforcement pattern 123d-1, 123d-2 may be thicker than the second thickness of the pad electrode PE. For example, the first thickness may be at least twofold the second thickness.

In the case where the power transmitted from the flexible circuit board and the printed circuit board has high voltage or a large amount of electric current, the power wiring transmitting it may have a great thickness. The first-first connection wiring 121a and the first-second connection wiring 121b disposed on the display area AA may be power wires for transmitting power to the pixel driving circuit PD. Accordingly, the first reinforcement pattern 123a-1, 123a-2 and the second reinforcement pattern 123b-1, 123b-2 formed by the same process as the first-first connection wiring 121a and the first-second connection wiring 121b may also have a great thickness. Additionally, the fourth reinforcement pattern 123d-1, 123d-2 may be formed in a great thickness to reduce resistance.

The one or more reinforcement patterns 123-1 may include a conductive material relatively having a rigidity, as they include the same material as the first connection wiring 121 and the second connection wiring 122. By disposing one or more reinforcement patterns 123-1 relatively having a rigidity in different layers of the upper multilayer structure, it is possible to prevent the stress from being applied to the upper multilayer structure. Accordingly, the occurrence of microcracks and film displacement phenomenon in the upper multilayer structure can be prevented. Due to this, the pad electrode PE and the flexible circuit board 157, see FIG. 8 can be stably connected to each other, thereby ensuring the reliability of the display device.

Additionally, the reinforcement pattern 123-1 can be formed in the process of forming the first connection wiring 121 or the second connection wiring 122, together with it. Accordingly, the manufacturing process can be simplified because no additional process is required.

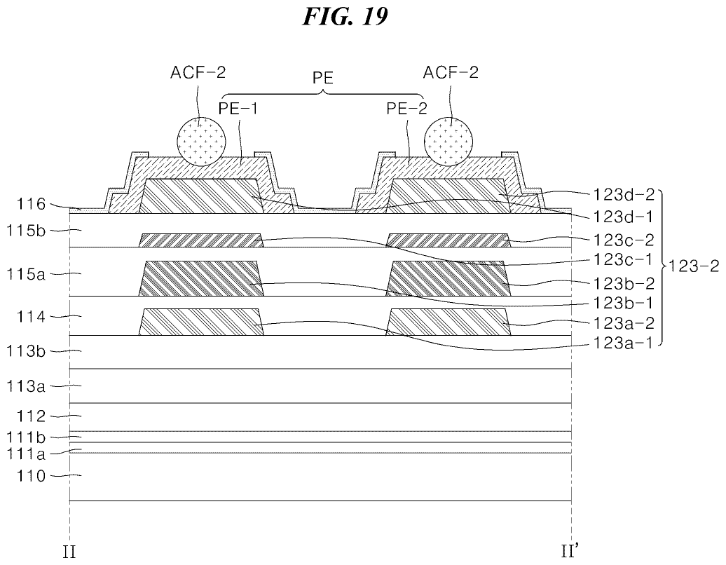

FIG. 19 is a cross-sectional view showing a pad part according to the third embodiment of the present disclosure. In FIG. 19, the same reference symbols will be given to the same components as those described with reference to FIG. 17, and the description thereof will be simplified or omitted. Also, for convenience of explanation, only the configuration of the conductive balls ACF-2 dispersed in the adhesive layer is shown.

According to the third embodiment of the present disclosure, the reinforcement pattern 123-2 differ from the reinforcement pattern 123-1 of the second embodiment in that it further includes a third reinforcement pattern 123c-1, 123c-2 disposed on the first insulating layer 115a in addition to a first reinforcement pattern 123a-1, 123a-2, a second reinforcement pattern 123b-1, 123b-2, and a fourth reinforcement pattern 123d-1, 123d-2.

The upper multilayer structure may include at least one or more of a first protective layer 113a, a second protective layer 113b, a third protective layer 114, a first insulating layer 115a, a second insulating layer 115b, and a third insulating layer 115c. Each of the layers constituting the upper multilayer structure may include an organic insulating material.

The reinforcement patterns 123-2 may be disposed to overlap with each other in the up and down direction (e.g., the vertical direction or the Y-direction) in the upper multilayer structure. For example, the reinforcement patterns 123-2 may include the first reinforcement pattern 123a-1, 123a-2 disposed on the second protective layer 113b, the second reinforcement pattern 123b-1, 123b-2 disposed on the third protective layer 114, the third reinforcement pattern 123c-1, 123c-2 disposed on the first insulating layer 115a, and the fourth reinforcement pattern 123d-1, 123d-2 disposed on the second insulating layer 115b. The plurality of pad electrodes PE may be disposed on the fourth reinforcement patterns 123d-1, 123d-2. The pad electrode PE may cover both side surfaces and the upper surface of the fourth reinforcement pattern 123d-1, 123d-2.

The first reinforcement pattern 123a-1, 123a-2, the second reinforcement pattern 123b-1, 123b-2, the third reinforcement pattern 123c-1, 123c-2, and the fourth reinforcement pattern 123d-1, 123d-2 may be disposed respectively to overlap with each other in the up and down direction. The first reinforcement pattern 123a-1, 123a-2, the second reinforcement pattern 123b-1, 123b-2, the third reinforcement pattern 123c-1, 123c-2, and the fourth reinforcement pattern 123d-1, 123d-2 may be spaced apart respectively from each other in the up and down direction by insulating material. For example, a spacing space may be provided between the first reinforcement pattern 123a-1, 123a-2 and the second reinforcement pattern 123b-1, 123b-2 by the third protective layer 114. For example, a spacing space may be provided between the second reinforcement pattern 123b-1, 123b-2 and the third reinforcement pattern 123c-1, 123c-2 by the first insulating layer 115a. For example, a spacing space may be provided between the third reinforcement pattern 123c-1, 123c-2 and the fourth reinforcement pattern 123d-1, 123d-2 by the second insulating layer 115b. However, this is not exhaustive. In another example, the second reinforcement pattern 123b-1, 123b-2 may be displaced directly in contact with the third reinforcement pattern 123c-1, 123c-2. For example, the upper surface of the second reinforcement pattern 123b-1, 123b-2 may be in contact with the rear surface of the third reinforcement pattern 123c-1, 123c-2. In this case, the width of the second reinforcement pattern 123b-1, 123b-2 may be greater than the width of the third reinforcement pattern 123c-1, 123c-2 and the width of the fourth reinforcement pattern 123d-1, 123d-2. The second reinforcement pattern 123b-1, 123b-2 may further improve the rigidity of the reinforcement pattern by being disposed directly in contact with the third reinforcement pattern 123c-1, 123c-2.

The first reinforcement pattern 123a-1, 123a-2, the second reinforcement pattern 123b-1, 123b-2, the third reinforcement pattern 123c-1, 123c-2, and the fourth reinforcement pattern 123d-1, 123d-2 may include the same material as the first connection wiring 121, see FIG. 8 disposed on the display area AA or the second connection wiring 122 disposed on the second non-display area NA2, and may be disposed in the same layer as one of them.

For example, the third reinforcement pattern 123c-1, 123c-2 may include the same material as the first-third connection wiring 121c and the second-third connection wiring 122c and may be disposed in the same layer as them.

The first reinforcement pattern 123a-1, 123a-2, the second reinforcement pattern 123b-1, 123b-2, the third reinforcement pattern 123c-1, 123c-2, and the fourth reinforcement pattern 123d-1, 123d-2 may each have different thicknesses. The first thickness of the first reinforcement pattern 123a-1, 123a-2, the second reinforcement pattern 123b-1, 123b-2, and the fourth reinforcement pattern 123d-1, 123d-2 may be thicker than the second thickness of the third reinforcement pattern 123c-1, 123c-2 and the pad electrode PE. For example, the first thickness may be at least twofold the second thickness.

Since the third reinforcement pattern 123c-1, 123c-2 has a relatively smaller thickness than the first reinforcement pattern 123a-1, 123a-2, the second reinforcement pattern 123b-1, 123b-2, and the fourth reinforcement pattern 123d-1, 123d-2, a flat surface can be easily formed even without forming the second insulating layer 115b with a great thickness on the upper side of the third reinforcement pattern.

The reinforcement patterns 123-2 can reinforce the upper multilayer structure more sturdily by further including the third reinforcement pattern 123c-1, 123c-2 disposed on the first insulating layer 115a. Accordingly, the occurrence of microcracks and film displacement phenomenon in the upper multilayer structure can be prevented, thereby stably connecting the pad electrode PE and the flexible circuit board 157, see FIG. 8 to each other.

In addition, the reinforcement pattern 123-2 can be formed in the process of forming the first connection wiring 121 or the second connection wiring 122, together with it, and thus the manufacturing process can be simplified and the manufacturing cost can be prevented from increasing due to the addition of a manufacturing process.

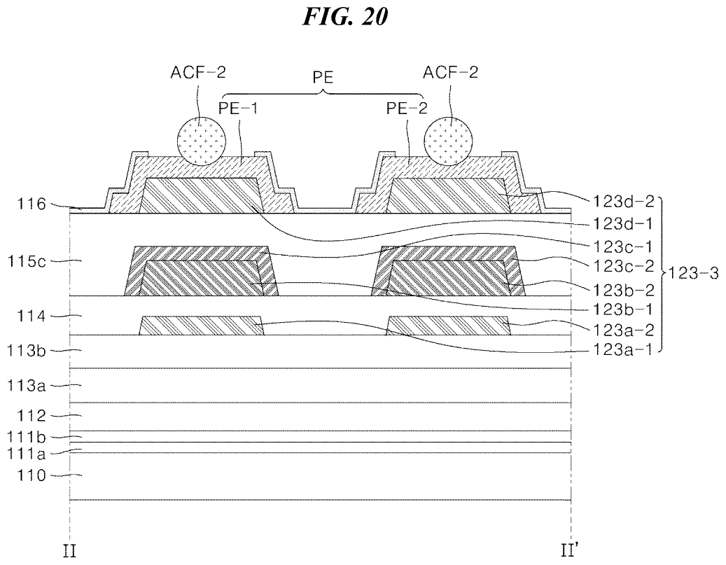

FIG. 20 is a cross-sectional view showing a pad part according to the fourth embodiment of the present disclosure. In FIG. 20, the same reference symbols will be given to the same components as those described with reference to FIG. 17, and the description thereof will be simplified or omitted. Also, for convenience of explanation, only the configuration of the conductive balls ACF-2 dispersed in the binder is shown.

According to the fourth embodiment of the present disclosure, the reinforcement pattern 123-3 differs from the reinforcement patterns 123-1, 123-2 of other embodiments in that the third reinforcement pattern 123c-1, 123c-2 has a shape that covers the second reinforcement pattern 123b-1, 123b-2.

The upper multilayer structure may include at least one or more of a first protective layer 113a, a second protective layer 113b, a third protective layer 114, a first insulating layer 115a, a second insulating layer 115b, and a third insulating layer 115c. Each of the layers constituting the upper multilayer structure may include an organic insulating material.

The reinforcement patterns 123-3 may be disposed to overlap with each other in the up and down direction (e.g., the vertical direction or the Y-direction) in the upper multilayer structure. For example, the reinforcement patterns 123-3 may include the first reinforcement pattern 123a-1, 123a-2 disposed on the second protective layer 113b, the second reinforcement pattern 123b-1, 123b-2 disposed on the third protective layer 114, the third reinforcement pattern 123c-1, 123c-2 disposed on the second reinforcement pattern 123b-1, 123b-2, and the fourth reinforcement pattern 123d-1, 123d-2 disposed on the third insulating layer 115c. The plurality of pad electrodes PE may be disposed on the fourth reinforcement patterns 123d-1, 123d-2. The pad electrode PE may cover both side surfaces and the upper surface of the fourth reinforcement pattern 123d-1, 123d-2.

The third reinforcement pattern 123c-1, 123c-2 may be disposed to cover the second reinforcement pattern 123b-1, 123b-2. For example, the third reinforcement pattern 123c-1, 123c-2 may be disposed to cover both side surfaces and the upper surface of the second reinforcement pattern 123b-1, 123b-2.

The first reinforcement pattern 123a-1, 123a-2, the second reinforcement pattern 123b-1, 123b-2, the third reinforcement pattern 123c-1, 123c-2, and the fourth reinforcement pattern 123d-1, 123d-2 may be disposed in different layers to overlap with each other in the up and down direction.

The second reinforcement pattern 123b-1, 123b-2 and the third reinforcement pattern 123c-1, 123c-2 may be disposed together on the same third protective layer 114. The third reinforcement pattern 123c-1, 123c-2 may be covered with the third insulating layer 115c. The third insulating layer 115c may have a thickness enough to cover the structure in which the second reinforcement pattern 123b-1, 123b-2 and the third reinforcement pattern 123c-1, 123c-2 are stacked.

The first reinforcement pattern 123a-1, 123a-2, the second reinforcement pattern 123b-1, 123b-2, the third reinforcement pattern 123c-1, 123c-2, and the fourth reinforcement pattern 123d-1, 123d-2 may include the same material as the first connection wiring 121, see FIG. 8 disposed on the display area AA or the second connection wiring 122 disposed on the second non-display area NA2, and may be disposed in the same layer as one of them.

For example, the third reinforcement pattern 123c-1, 123c-2 may include the same material as the first-third connection wiring 121c and the second-third connection wiring 122c and may be disposed in the same layer as them.

Since the reinforcement pattern 123-3 further includes a structure in which the third reinforcement pattern 123c-1, 123c-2 is stacked on the second reinforcement pattern 123b-1, 123b-2, it is possible to reinforce the upper multilayer structure more sturdily. Accordingly, the occurrence of microcracks and film displacement phenomenon in the upper multilayer structure can be prevented, thereby stably connecting the pad electrode PE and the flexible circuit board 157, see FIG. 8 to each other.

In addition, the reinforcement pattern 123-3 can be formed in the process of forming the first connection wiring 121 or the second connection wiring 122, together with it, and thus the manufacturing process can be simplified and the manufacturing cost can be prevented from increasing due to the addition of a manufacturing process.

Meanwhile, the conductive ball ACF-2 dispersed in the adhesive layer is in contact with the pad electrode PE, a physical force is applied to the pad electrode PE, and the third insulating layer 115c of the upper multilayer structure, which is in contact with the pad electrode PE, may be subjected to the greatest amount of stress caused by the external force. Accordingly, it is possible to construct, in the third insulating layer 115c, the reinforcement pattern capable of preventing stress caused by physical force.

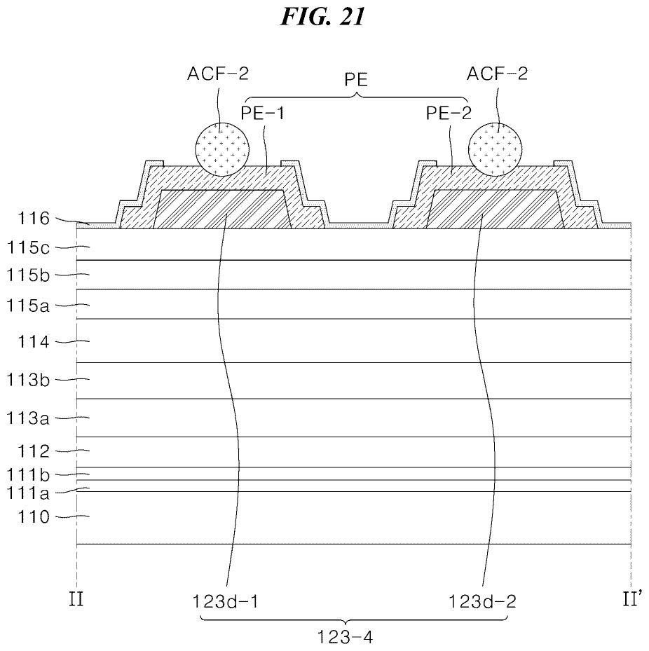

FIG. 21 is a cross-sectional view showing a pad part according to the fifth embodiment of the present disclosure. In FIG. 21, the same reference symbols will be given to the same components as those described with reference to FIG. 17, and the description thereof will be simplified or omitted. Also, for convenience of explanation, only the configuration of the conductive balls ACF-2 dispersed in the adhesive layer ACF is shown.

According to the fifth embodiment of the present disclosure, the reinforcement pattern 123-4 differs from the reinforcement patterns 123-1, 123-2, 123-3 of other embodiments in that it has a shape in which the fourth reinforcement pattern 123d-1, 123d-2 is disposed between the third insulating layer 115c and the pad electrode PE.

The upper multilayer structure may include at least one or more of a first protective layer 113a, a second protective layer 113b, a third protective layer 114, a first insulating layer 115a, a second insulating layer 115b, and a third insulating layer 115c. Each of the layers constituting the upper multilayer structure may include an organic insulating material.

The reinforcement pattern 123-4 may be disposed on the third insulating layer 115c disposed at the uppermost portion of the upper multilayer structure. The reinforcement patterns 123-4 may include a first portion 123d-1 and a second portion 123d-2 corresponding to the first pad electrode PE-1 and the second pad electrode PE-2, respectively. The plurality of pad electrodes PE may be disposed on the reinforcement patterns 123-4. Each of the plurality of pad electrodes PE may cover both side surfaces and the upper surface of each of the reinforcement patterns 123-4. For example, the reinforcement pattern 123-4 may have the same shape as the pad electrode PE; however, this is not exhaustive.

The reinforcement pattern 123-4 may include the same material as the first connection wiring 121 (see FIG. 8) disposed on the display area AA or the second connection wiring 122 disposed on the second non-display area NA2.

The reinforcement pattern 123-4 may be disposed between the pad electrode PE and the third insulating layer 115c and may be disposed at a portion where a physical force is applied to the conductive ball ACF-2. Even when the physical force is applied to the conductive ball ACF-2, it is possible to prevent stress from being applied to the third insulating layer 115c, which is an organic insulating material, because the reinforcement pattern 123-4 including a relatively hard conductive material is disposed in the lower side of the pad electrode PE.

Accordingly, the occurrence of microcracks and film displacement phenomenon in the upper multilayer structure can be prevented, thereby stably connecting the pad electrode PE and the flexible circuit board 157, see FIG. 8 to each other.

In addition, the reinforcement pattern 123-4 can be formed in the process of forming the first connection wiring 121 or the second connection wiring 122, together with it, and thus the manufacturing process can be simplified and the manufacturing cost can be prevented from increasing due to the addition of a manufacturing process.

In addition, by disposing the reinforcement pattern 123-4 as a single layer between the pad electrode PE and the third insulating layer 115c, there is an effect of reducing the manufacturing process.

The display device according to various embodiments of the present disclosure may be described as follows.

A display device according to an embodiment of the present disclosure may include a substrate including a display area and a non-display area outside the display area; a plurality of pixel driving circuits disposed on the display area of the substrate; a plurality of light-emitting elements disposed on the pixel driving circuit and electrically connected to each pixel driving circuit; a plurality of pad electrodes disposed on the non-display area of the substrate; at least one or more multilayer insulating structure disposed in a lower side of the plurality of pad electrodes; and one or more reinforcement patterns disposed between the pad electrode and the multilayer insulating structure.

According to various embodiments of the present disclosure, the multilayer insulating structure may include a lower multilayer structure disposed in a lower side of a substrate adhesive layer disposed on the substrate, and an upper multilayer structure disposed in an upper side of the substrate adhesive layer.

According to various embodiments of the present disclosure, the upper multilayer structure may include an organic insulating material.

According to various embodiments of the present disclosure, the one or more reinforcement patterns may be disposed in different layers of the multilayer insulating structure to overlap with each other in an up and down direction.

According to various embodiments of the present disclosure, the upper multilayer structure may include a first protective layer on the substrate adhesive layer; a second protective layer on the first protective layer; a third protective layer on the second protective layer; a first insulating layer on the third protective layer; a second insulating layer on the first insulating layer; and a third insulating layer disposed on the second insulating layer and disposed below the pad electrode, and the one or more reinforcement patterns may be disposed between the pad electrode and the third insulating layer.

According to various embodiments of the present disclosure, the pad electrode may cover both side surfaces and an upper surface of the reinforcement pattern.

According to various embodiments of the present disclosure, the upper multilayer structure may include a first protective layer on the substrate adhesive layer; a second protective layer on the first protective layer; a third protective layer on the second protective layer; a first insulating layer on the third protective layer; and a second insulating layer on the first insulating layer, and the one or more reinforcement patterns may be disposed at the second protective layer, the third protective layer, the first insulating layer, and the second insulating layer so that the one or more reinforcement patterns are disposed at different layers, corresponding to an area where the pad electrode is disposed, and the pad electrode may cover both side surfaces and an upper surface of the reinforcement pattern.

According to various embodiments of the present disclosure, the upper multilayer structure may include a first protective layer on the substrate adhesive layer; a second protective layer on the first protective layer; a third protective layer on the second protective layer; a first insulating layer on the third protective layer; and a second insulating layer on the first insulating layer, and the one or more reinforcement patterns may be disposed at the second protective layer, the third protective layer, and the second insulating layer so that the one or more reinforcement patterns are disposed at different layers, corresponding to an area where the pad electrode is disposed.

According to various embodiments of the present disclosure, the one or more reinforcement pattern may include a first reinforcement pattern disposed on the second protective layer; a second reinforcement pattern disposed on the third protective layer; a third reinforcement pattern disposed on the first insulating layer; and a fourth reinforcement pattern disposed on the second insulating layer, and the first reinforcement pattern, the second reinforcement pattern, and the fourth reinforcement pattern may have a first thickness, and the pad electrode and the third reinforcement pattern may have a second thickness different from the first thickness.

According to various embodiments of the present disclosure, the first thickness may be at least twofold the second thickness.

According to various embodiments of the present disclosure, the upper multilayer structure may include a first protective layer on the substrate adhesive layer; a second protective layer on the first protective layer; a third protective layer on the second protective layer; and an insulating layer on the third protective layer, and the one or more reinforcement patterns may be disposed at the second protective layer and the third protective layer so that the one or more reinforcement patterns are disposed at different layers, corresponding to an area where the pad electrode is disposed.

According to various embodiments of the present disclosure, the one or more reinforcement pattern may include a first reinforcement pattern disposed on the second protective layer; a second reinforcement pattern disposed on the third protective layer; and a third reinforcement pattern covering the second reinforcement pattern.

According to various embodiments of the present disclosure, the display device may further include an adhesive layer disposed on the plurality of pad electrodes; and a flexible circuit board electrically connected to each of the plurality of pad electrodes through the adhesive layer, and the adhesive layer may include a binder having a plurality of conductive balls dispersed therein, and the conductive balls may be in contact with each of the plurality of pad electrodes.

According to various embodiments of the present disclosure, the plurality of light-emitting elements may include a micro light-emitting element.

According to various embodiments of the present disclosure, the plurality of light-emitting elements may include a pair of light-emitting elements which emit light of a same color, and one light-emitting element of the pair of light-emitting elements may be a main light-emitting element, and another light-emitting element may be a redundant light-emitting element.

According to various embodiments of the present disclosure, the pixel driving circuit may include a micro driver.

According to various embodiments of the present disclosure, the plurality of light-emitting elements includes a micro light-emitting element having a vertical structure.

According to various embodiments of the present disclosure, a bank in which each of the light-emitting elements is disposed; and a first electrode disposed between the bank and each of the light-emitting elements, wherein the light-emitting element is electrically connected to the first electrode by eutectic bonding.

While the embodiments of the present disclosure have been described in detail with reference to the accompanying drawings, it should be understood by a person skilled in the art that the present disclosure is not necessarily limited to the above embodiments, and the above embodiments can be modified without departing from the technical idea of the present disclosure. Accordingly, the embodiments disclosed in the present disclosure are not intended to limit the technical idea of the present disclosure but to explain the technical idea of the present disclosure, and the scope of the technical idea of the present disclosure is not limited by these embodiments. Therefore, it should be understood that the embodiments described above are given only as an example in all respects but not for a limiting purpose.

What is claimed is:

1. A display device comprising:
a substrate including a display area and a non-display area outside the display area;
a plurality of pixel driving circuits on the display area of the substrate;
a plurality of light-emitting elements on the plurality of pixel driving circuits, the plurality of light-emitting elements electrically connected to the plurality of pixel driving circuits;
a plurality of pad electrodes on the non-display area of the substrate;
at least one multilayer insulating structure disposed in a lower side of the plurality of pad electrodes; and
one or more reinforcement patterns between the plurality of pad electrodes and the at least one multilayer insulating structure.

2. The display device of claim 1, wherein the at least one multilayer insulating structure includes:
a lower multilayer structure disposed in a lower side of a substrate adhesive layer that is disposed on the substrate; and
an upper multilayer structure disposed in an upper side of the substrate adhesive layer, and
wherein the lower multilayer structure and the upper multilayer structure include different materials from each other.

3. The display device of claim 2, wherein the lower multilayer structure includes an inorganic insulating material and the upper multilayer structure includes an organic insulating material.

4. The display device of claim 1, wherein the one or more reinforcement patterns are in different layers of the at least one multilayer insulating structure and overlap with each other in an up and down direction.

5. The display device of claim 2, wherein the upper multilayer structure includes:
a first protective layer on the substrate adhesive layer;
a second protective layer on the first protective layer;
a third protective layer on the second protective layer;
a first insulating layer on the third protective layer;
a second insulating layer on the first insulating layer; and
a third insulating layer on the second insulating layer and below the plurality of pad electrodes, and
wherein the one or more reinforcement patterns are between the plurality of pad electrodes and the third insulating layer.

6. The display device of claim 5, wherein the plurality of pad electrodes cover both side surfaces and an upper surface of the one or more reinforcement patterns.

7. The display device of claim 2, wherein the upper multilayer structure includes:
a first protective layer on the substrate adhesive layer;
a second protective layer on the first protective layer;
a third protective layer on the second protective layer;
a first insulating layer on the third protective layer; and
a second insulating layer on the first insulating layer,
wherein the one or more reinforcement patterns are disposed at the second protective layer, the third protective layer, the first insulating layer, and the second insulating layer such that the one or more reinforcement patterns are on different layers corresponding to an area where the plurality of pad electrodes are disposed, and
wherein the plurality of pad electrodes cover both side surfaces and an upper surface of the one or more reinforcement patterns.

8. The display device of claim 2, wherein the upper multilayer structure includes:
a first protective layer on the substrate adhesive layer;
a second protective layer on the first protective layer;
a third protective layer on the second protective layer;
a first insulating layer on the third protective layer; and
a second insulating layer on the first insulating layer, and
wherein the one or more reinforcement patterns are disposed at the second protective layer, the third protective layer, and the second insulating layer such that the one or more reinforcement patterns are at different layers corresponding to an area where the plurality of pad electrodes are disposed.

9. The display device of claim 7, wherein the one or more reinforcement patterns includes:
a first reinforcement pattern on the second protective layer;
a second reinforcement pattern on the third protective layer;
a third reinforcement pattern on the first insulating layer; and
a fourth reinforcement pattern on the second insulating layer, and
wherein the first reinforcement pattern, the second reinforcement pattern, and the fourth reinforcement pattern have a first thickness and the plurality of pad electrodes and the third reinforcement pattern have a second thickness that is different from the first thickness.

10. The display device of claim 9, wherein the first thickness is at least twice the second thickness.

11. The display device of claim 2, wherein the upper multilayer structure includes:
a first protective layer on the substrate adhesive layer;
a second protective layer on the first protective layer;
a third protective layer on the second protective layer; and
an insulating layer on the third protective layer, and
wherein the one or more reinforcement patterns are disposed at the second protective layer and the third protective layer such that the one or more reinforcement patterns are at different layers corresponding to an area where the plurality of pad electrodes are disposed.

12. The display device of claim 11, wherein the one or more reinforcement patterns includes:
a first reinforcement pattern on the second protective layer;
a second reinforcement pattern on the third protective layer; and
a third reinforcement pattern covering the second reinforcement pattern.

13. The display device of claim 1, further comprising:
an adhesive layer on the plurality of pad electrodes; and
a flexible circuit board electrically connected to each of the plurality of pad electrodes through the adhesive layer,
wherein the adhesive layer includes a binder having a plurality of conductive balls dispersed therein, and
wherein the plurality of conductive balls are in contact with each of the plurality of pad electrodes.

14. The display device of claim 1, wherein the plurality of light-emitting elements include a micro light-emitting element.

15. The display device of claim 1, wherein the plurality of light-emitting elements include a pair of light-emitting elements which emit light of a same color, and
wherein one light-emitting element of the pair of light-emitting elements is a main light-emitting element and another light-emitting element of the pair is a redundant light-emitting element.

16. The display device of claim 1, wherein the plurality of pixel driving circuits include a micro driver.

17. The display device of claim 1, wherein the plurality of light-emitting elements include a micro light-emitting element having a vertical structure.

18. The display device of claim 5, further comprising:
a bank in which each of the plurality of light-emitting elements is disposed; and
a first electrode between the bank and each of the plurality of light-emitting elements,
wherein a light-emitting element from the plurality of light-emitting elements is electrically connected to the first electrode.

19. The display device of claim 5, further comprising:
a passivation layer disposed on each of the plurality of pad electrodes,
wherein the passivation layer includes an inorganic insulating material, and
wherein the passivation layer covers side surfaces and upper edges of each of the plurality of pad electrodes, and covers the third insulating layer between the plurality of pad electrodes.
